(19) United States
(12) Patent Application Publication
(10) Pub. No.: US 2024/0162311 A1
(43) Pub. Date: May 16, 2024

(54) SEMICONDUCTOR DEVICE AND METHOD OF MANUFACTURING THE SAME

(71) Applicant: SAMSUNG ELECTRONICS CO., LTD., Suwon-si (KR)

(72) Inventors: Darong OH, Suwon-si (KR); Ho-Jun KIM, Suwon-si (KR); Jeewoong KIM, Suwon-si (KR)

(21) Appl. No.: 18/225,777

(22) Filed: Jul. 25, 2023

(30) Foreign Application Priority Data
Nov. 11, 2022 (KR) 10-2022-0150795

(51) Int. Cl. H01L 29/417; H01L 23/48; H01L 29/06; H01L 29/423; H01L 29/66; H01L 29/775; H01L 29/786

(52) U.S. Cl. CPC H01L 29/41733; H01L 23/481; H01L 29/0673; H01L 29/42392; H01L 29/6656; H01L 29/775; H01L 29/78696

(57) ABSTRACT

A semiconductor device comprising a substrate including an active pattern, a channel pattern and a source/drain pattern that are on the active pattern, the source/drain pattern connected to the channel pattern, a gate electrode on the channel pattern, an active contact on the source/drain pattern, an upper contact being adjacent to the active contact and extending into the substrate, a lower power interconnection line buried in the substrate, and a power delivery network layer on a bottom surface of the substrate, wherein the lower power interconnection line includes a connection portion connected to the upper contact, and a lower portion of the upper contact protrudes into the connection portion.

### CROSS-REFERENCE TO RELATED APPLICATIONS

Korean Patent Application No. 10-2022-0150795, filed on Nov. 11, 2022, in the Korean Intellectual Property Office, is hereby incorporated by reference in its entirety.

### BACKGROUND

### 1. Field

A semiconductor device and a method of manufacturing the same is disclosed.

### 2. Description of the Related Art

Semiconductor devices may include integrated circuits including metal-oxide-semiconductor field effect transistors (MOSFETs).

### SUMMARY

Embodiments are directed to a semiconductor device including a substrate including an active pattern, a channel pattern and a source/drain pattern that are on the active pattern, the source/drain pattern connected to the channel pattern, a gate electrode on the channel pattern, an active contact on the source/drain pattern, an upper contact being adjacent to the active contact and extending into the substrate, a lower power interconnection line buried in the substrate, and a power delivery network layer on a bottom surface of the substrate, wherein the lower power interconnection line includes a connection portion connected to the upper contact, and a lower portion of the upper contact protruding into the connection portion.

Embodiments are also directed to a semiconductor device including a substrate including an active pattern, a channel pattern and a source/drain pattern that is on the active pattern, the source/drain pattern is connected to the channel pattern, a gate electrode on the channel pattern, an active contact on the source/drain pattern, an upper contact being adjacent to the active contact and extending into the substrate, a first liner on a sidewall of the upper contact, a lower power interconnection line buried in the substrate, the lower power interconnection line being in contact with the upper contact, a lower spacer between the lower power interconnection line and the substrate, and a power delivery network layer on a bottom surface of the substrate, wherein the lower spacer includes a second liner and an oxide spacer, and the second liner includes a silicon-based insulating material different from that of the oxide spacer.

Embodiments are also directed to a semiconductor device including a substrate including an active pattern, a channel pattern and a source/drain pattern that are on the active pattern, the source/drain pattern connected to the channel pattern, a gate electrode on the channel pattern, a gate insulating layer between the gate electrode and the channel pattern, a gate spacer on a sidewall of the gate electrode, a gate capping pattern on a top surface of the gate electrode, an interlayer insulating layer covering the source/drain pattern and the gate capping pattern, an active contact penetrating the interlayer insulating layer electrically connected to the source/drain pattern, a metal-semiconductor compound layer between the active contact and the source/drain pattern, a gate contact penetrating the interlayer insulating layer and the gate capping pattern electrically connected to the gate electrode, an upper contact penetrating the interlayer insulating layer and extending into the substrate, a first metal layer on the interlayer insulating layer, the first metal layer including a first interconnection line electrically connecting the active contact and the upper contact to each other, a second metal layer on the first metal layer, the second metal layer including a second interconnection line electrically connected to the first metal layer, a lower power interconnection line buried in the substrate, a first oxide spacer and a second oxide spacer which are on both sides of the lower power interconnection line, respectively, and a power delivery network layer on a bottom surface of the substrate, wherein a thickness of the first oxide spacer is different from a thickness of the second oxide spacer.

### BRIEF DESCRIPTION OF THE DRAWINGS

Features will become apparent to those of skill in the art by describing in detail exemplary embodiments with reference to the attached drawings in which:

FIGS. 1 to 3 are conceptual views of logic cells of a semiconductor device according to example embodiments.

FIG. 4 is a plan view of a semiconductor device according to example embodiments.

FIGS. 5A, 5B, 5C, 5D and 5E are cross-sectional views taken along lines A-A′, B-B′, C-C′, D-D′ and E-E′ of FIG. 4, respectively.

FIG. 6 is an enlarged cross-sectional view of a region ‘M’ of FIG. 5D.

FIGS. 7A to 17 are cross-sectional views of a method of manufacturing a semiconductor device according to example embodiments.

FIGS. 18 and 19 are enlarged cross-sectional views of the region ‘M’ of FIG. 5D of semiconductor devices according to example embodiments.

FIGS. 20A, 20B and 20C are cross-sectional views taken along the lines A-A′, B-B′ and E-E′ of FIG. 4, respectively, of a semiconductor device according to example embodiments.

### DETAILED DESCRIPTION

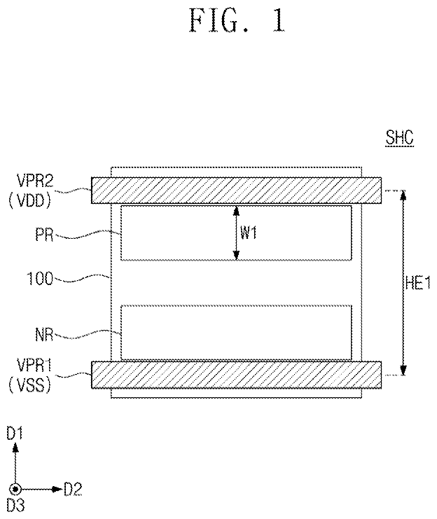

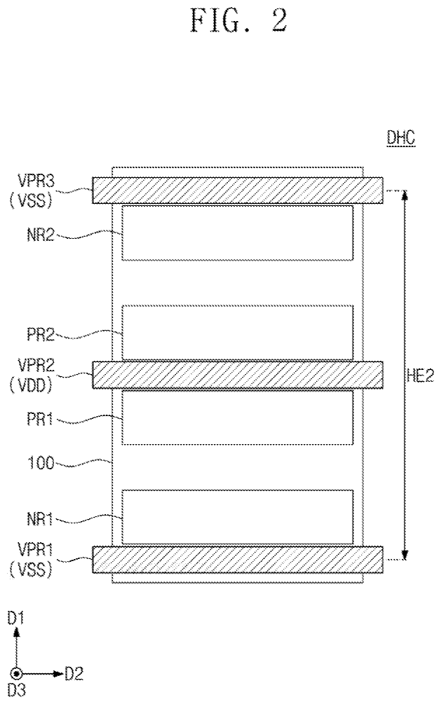

FIGS. 1 to 3 are conceptual views of logic cells of a semiconductor device according to example embodiments. Referring to FIG. 1, a single height cell SHC may be provided. More particularly, a first lower power interconnection line VPR1 and a second lower power interconnection line VPR2 may be provided in a lower portion of a substrate 100. The first lower power interconnection line VPR1 may be a path through which a source voltage VSS (e.g., a ground voltage) is provided. The second lower power interconnection line VPR2 may be a path through which a drain voltage VDD (e.g., a power voltage) is provided.

The single height cell SHC may be defined between the first lower power interconnection line VPR1 and the second lower power interconnection line VPR2. The single height cell SHC may include a PMOSFET region PR and an NMOSFET region NR. In other words, the single height cell SHC may have a CMOS structure provided between the first lower power interconnection line VPR1 and the second lower power interconnection line VPR2.

Each of the PMOSFET region PR and the NMOSFET region NR may have a first width W1 in a first direction D1. A length of the single height cell SHC in the first direction D1 may be defined as a first height HE1. The first height HE1 may be substantially equal to a distance (e.g., a pitch) between the first lower power interconnection line VPR1 and the second lower power interconnection line VPR2.

The single height cell SHC may form a logic cell. In the present specification, the logic cell may mean a logic element (e.g., an AND element, an OR element, an XOR element, an XNOR element, or an inverter) for performing a specific function. In other words, the logic cell may include transistors and interconnection lines connecting the transistors to each other, which constitute the logic element.

Referring to FIG. 2, a double height cell DHC may be provided. More particularly, a first lower power interconnection line VPR1, a second lower power interconnection line VPR2 and a third lower power interconnection line VPR3 may be on a substrate 100. The second lower power interconnection line VPR2 may be between the first lower power interconnection line VPR1 and the third lower power interconnection line VPR3. The third lower power interconnection line VPR3 may be a path through which the source voltage VSS is provided.

The double height cell DHC may be defined between the first lower power interconnection line VPR1 and the third lower power interconnection line VPR3. The double height cell DHC may include a first PMOSFET region PR1, a second PMOSFET region PR2, a first NMOSFET region NR1, and a second NMOSFET region NR2.

The first NMOSFET region NR1 may be adjacent to the first lower power interconnection line VPR1. The second NMOSFET region NR2 may be adjacent to the third lower power interconnection line VPR3. The first and second PMOSFET regions PR1 and PR2 may be adjacent to the second lower power interconnection line VPR2. The second lower power interconnection line VPR2 may be between the first and second PMOSFET regions PR1 and PR2 when viewed in a plan view.

A length of the double height cell DHC in the first direction D1 may be defined as a second height HE2. The second height HE2 may be about twice the first height HE1 of FIG. 1. The first and second PMOSFET regions PR1 and PR2 of the double height cell DHC may be combined with each other to operate as a single PMOSFET region. Thus, a size of a channel of a PMOS transistor of the double height cell DHC may be greater than a size of a channel of a PMOS transistor of the single height cell SHC described above in FIG. 1.

In an implementation, the size of the channel of the PMOS transistor of the double height cell DHC may be about twice the size of the channel of the PMOS transistor of the single height cell SHC. As a result, the double height cell DHC may operate at a higher speed than the single height cell SHC. The double height cell DHC shown in FIG. 2 may be defined as a multi-height cell. The multi-height cell may include a triple height cell of which a cell height may be about three times that of the single height cell SHC.

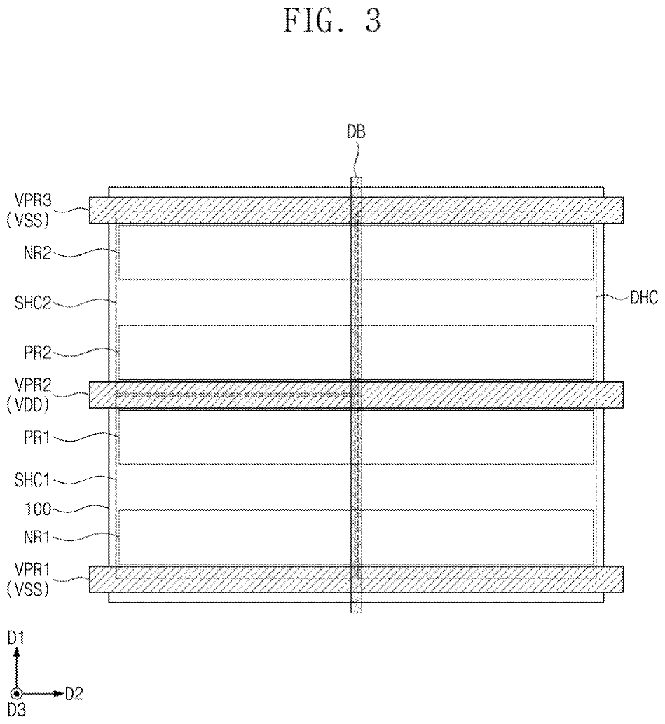

Referring to FIG. 3, a first single height cell SHC1, a second single height cell SHC2 and a double height cell DHC may be two-dimensionally on a substrate 100. The first single height cell SHC1 may be between first and second lower power interconnection lines VPR1 and VPR2. The second single height cell SHC2 may be between second and third lower power interconnection lines VPR2 and VPR3. The second single height cell SHC2 may be adjacent to the first single height cell SHC1 in the first direction D1.

The double height cell DHC may be between the first and third lower power interconnection lines VPR1 and VPR3. The double height cell DHC may be adjacent to the first and second single height cells SHC1 and SHC2 in a second direction D2.

An isolation structure DB may be provided between the first single height cell SHC1 and the double height cell DHC and between the second single height cell SHC2 and the double height cell DHC. An active region of the double height cell DHC may be electrically isolated from an active region of each of the first and second single height cells SHC1 and SHC2 by the isolation structure DB.

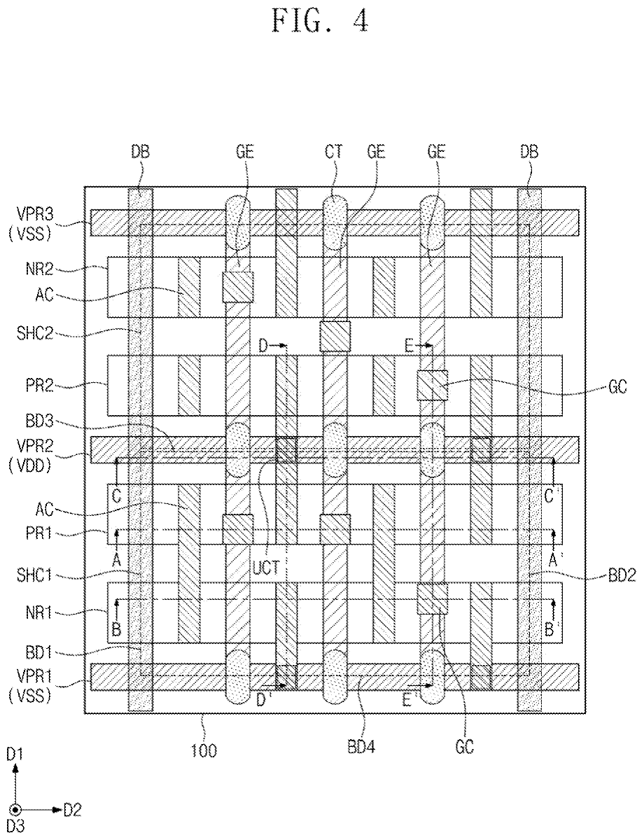

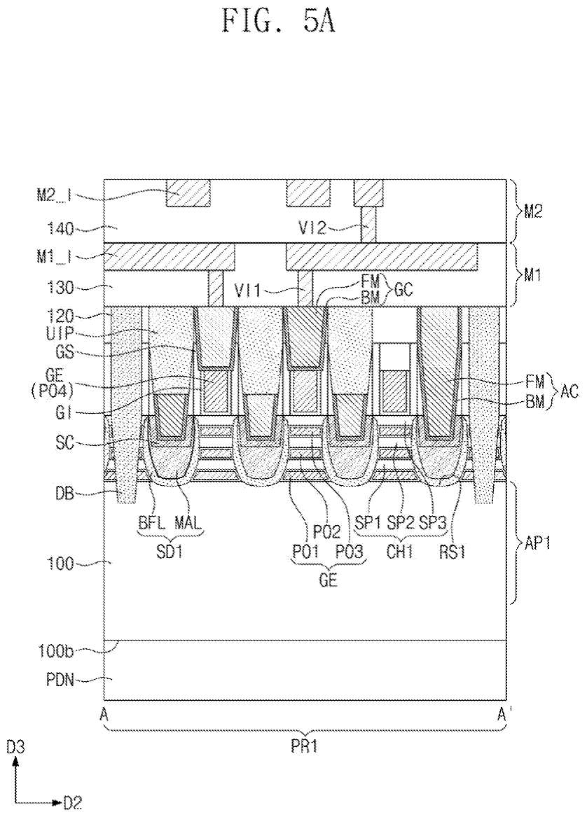

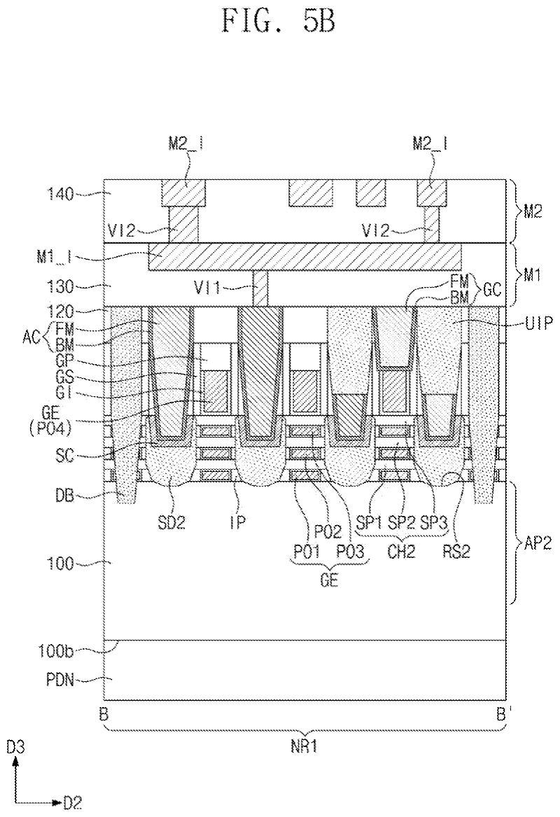

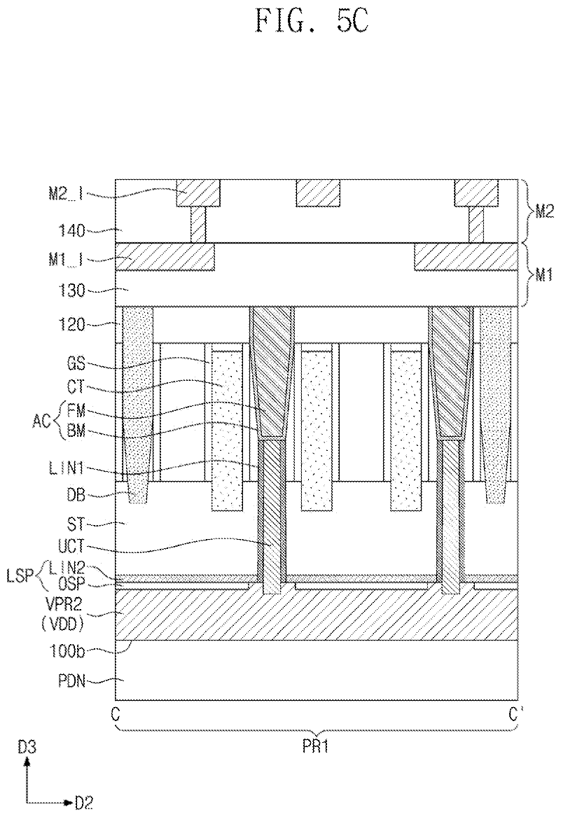

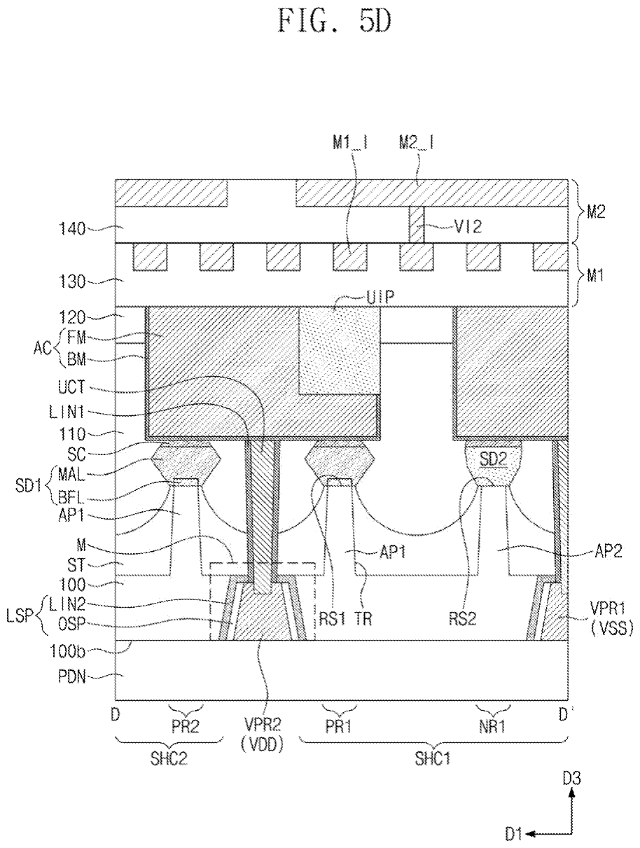

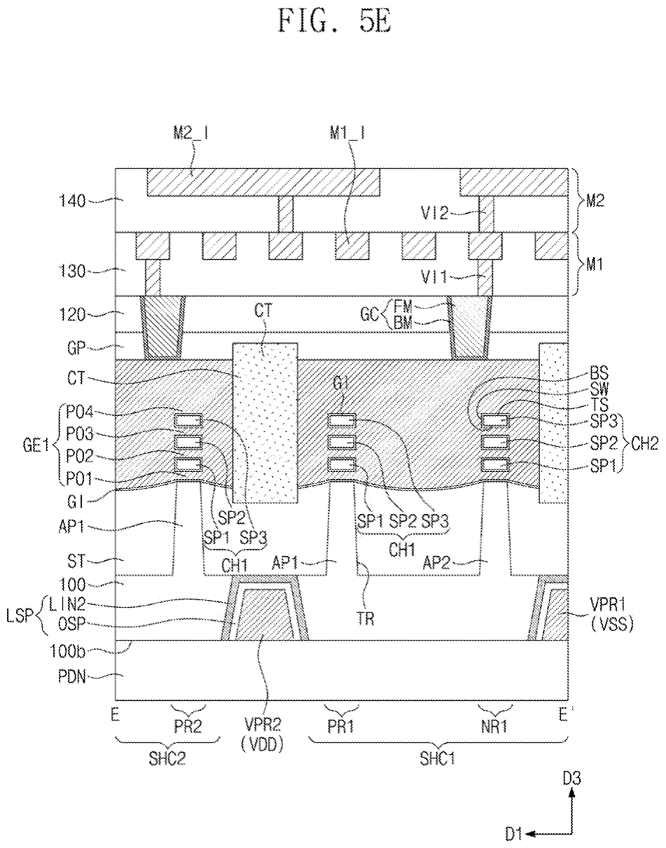

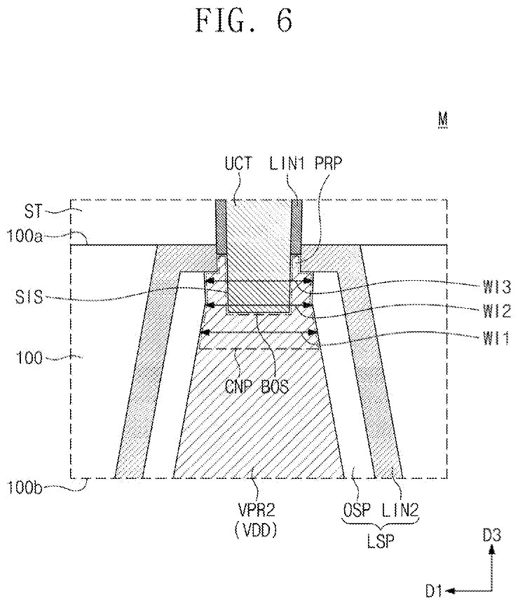

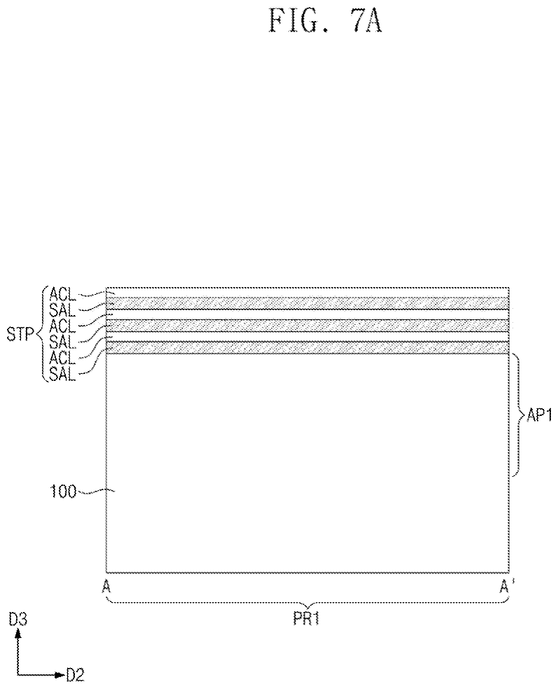

FIG. 4 is a plan view of a semiconductor device according to example embodiments. FIGS. 5A, 5B, 5C, 5D and 5E are cross-sectional views taken along lines A-A′, B-B′, C-C′, D-D′ and E-E′ of FIG. 4, respectively. FIG. 6 is an enlarged cross-sectional view of a region ‘M’ of FIG. 5D. The semiconductor device of FIGS. 4 and 5A to 5E is a more detailed example of the first and second single height cells SHC1 and SHC2 of FIG. 3.

Referring to FIGS. 4 and 5A to 5E, first and second single height cells SHC1 and SHC2 may be on a substrate 100. Logic transistors constituting a logic circuit may be on each of the first and second single height cells SHC1 and SHC2. The substrate 100 may be a semiconductor substrate including silicon, germanium or silicon-germanium, or a compound semiconductor substrate. In an implementation, the substrate 100 may be a silicon substrate.

The substrate 100 may have a first PMOSFET region PR1, a second PMOSFET region PR2, a first NMOSFET region NR1, and a second NMOSFET region NR2. Each of the first PMOSFET region PR1, the second PMOSFET region PR2, the first NMOSFET region NR1 and the second NMOSFET region NR2 may extend in the second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first active pattern AP1 and a second active pattern AP2 may be defined by a trench TR in an upper portion of the substrate 100. The first active pattern AP1 may be on each of the first and second PMOSFET regions PR1 and PR2. The second active pattern AP2 may be on each of the first and second NMOSFET regions NR1 and NR2. The first and second active patterns AP1 and AP2 may extend in the second direction D2. The first and second active patterns AP1 and AP2 may be portions of the substrate 100, which vertically protrude.

A device isolation layer ST may fill the trench TR. The device isolation layer ST may include a silicon oxide layer. The device isolation layer ST may not cover first and second channel patterns CH1 and CH2 to be described later.

A first channel pattern CH1 may be on the first active pattern AP1. A second channel pattern CH2 may be on the second active pattern AP2. Each of the first channel pattern CH1 and the second channel pattern CH2 may include a first semiconductor pattern SP1, a second semiconductor pattern SP2 and a third semiconductor pattern SP3, which may be sequentially stacked. The first to third semiconductor patterns SP1, SP2 and SP3 may be spaced apart from each other in a vertical direction (e.g., a third direction D3).

Each of the first to third semiconductor patterns SP1, SP2 and SP3 may include silicon (Si), germanium (Ge), or silicon-germanium (SiGe). In an implementation, each of the first to third semiconductor patterns SP1, SP2 and SP3 may include crystalline silicon. Each of the first to third semiconductor patterns SP1, SP2 and SP3 may be a nanosheet. As used herein, the term “or” is not an exclusive term, e.g., “A or B” would include A, B, or A and B.

A plurality of first source/drain patterns SD1 may be on the first active pattern AP1. A plurality of first recesses RS1 may be on the first active pattern AP1. The first source/drain patterns SD1 may be provided in the first recesses RS1, respectively. The first source/drain patterns SD1 may be dopant regions having a first conductivity type (e.g., a p-type). The first channel pattern CH1 may be between a pair of the first source/drain patterns SD1. In other words, the first to third semiconductor patterns SP1, SP2 and SP3 stacked sequentially may connect the pair of first source/drain patterns SD1 to each other.

A plurality of second source/drain patterns SD2 may be on the second active pattern AP2. A plurality of second recesses RS2 may be on the second active pattern AP2. The second source/drain patterns SD2 may be provided in the second recesses RS2, respectively. The second source/drain patterns SD2 may be dopant regions having a second conductivity type (e.g., an n-type). The second channel pattern CH2 may be between a pair of the second source/drain patterns SD2. In other words, the first to third semiconductor patterns SP1, SP2 and SP3 stacked sequentially may connect the pair of second source/drain patterns SD2 to each other.

The first and second source/drain patterns SD1 and SD2 may be epitaxial patterns formed by a selective epitaxial growth (SEG) process. In an implementation, a top surface of each of the first and second source/drain patterns SD1 and SD2 may be located at substantially the same level as a top surface of the third semiconductor pattern SP3. Alternatively, the top surface of each of the first and second source/drain patterns SD1 and SD2 may be higher than the top surface of the third semiconductor pattern SP3.

The first source/drain patterns SD1 may include a semiconductor element (e.g., SiGe) of which a lattice constant may be greater than a lattice constant of a semiconductor element of the substrate 100. Thus, the pair of first source/drain patterns SD1 may provide compressive stress to the first channel pattern CH1 therebetween. The second source/drain patterns SD2 may include the same semiconductor element (e.g., Si) as the substrate 100.

Each of the first source/drain patterns SD1 may include a buffer layer BFL and a main layer MAL on the buffer layer BFL. Referring again to FIG. 5A, the buffer layer BFL may cover an inner surface of the first recess RS1. In some embodiments, the buffer layer BFL may have a substantially uniform thickness. In an implementation, a thickness, in the third direction D3, of the buffer layer BFL on a bottom of the first recess RS1 may be substantially equal to a thickness, in the second direction D2, of the buffer layer BFL on an inner sidewall of an upper portion of the first recess RS1.

In certain embodiments, a thickness of the buffer layer BFL may become less from a lower portion of the buffer layer BFL toward an upper portion of the buffer layer BFL. In an implementation, a thickness, in the third direction D3, of the buffer layer BFL on the bottom of the first recess RS1 may be greater than a thickness, in the second direction D2, of the buffer layer BFL on the inner sidewall of the upper portion of the first recess RS1. The buffer layer BFL may have a U-shape along a profile of the first recess RS1.

The main layer MAL may fill a most portion of a remaining region of the first recess RS1 except the buffer layer BFL. A volume of the main layer MAL may be greater than a volume of the buffer layer BFL. Each of the buffer layer BFL and the main layer MAL may include silicon-germanium (SiGe). More particularly, the buffer layer BFL may contain a relatively low concentration of germanium (Ge). The buffer layer BFL may contain silicon (Si) except germanium (Ge). A concentration of germanium (Ge) of the buffer layer BFL may range from 0 at % to 10 at %.

The main layer MAL may contain a relatively high concentration of germanium (Ge). In an implementation, a concentration of germanium (Ge) of the main layer MAL may range from 30 at % to 70 at %. The concentration of germanium (Ge) of the main layer MAL may increase toward the third direction D3. In an implementation, the main layer MAL adjacent to the buffer layer BFL may have a germanium (Ge) concentration of about 40 at %, and an upper portion of the main layer MAL may have a germanium (Ge) concentration of about 60 at %.

Each of the buffer layer BFL and the main layer MAL may include dopants (e.g., boron, gallium, or indium) for allowing the first source/drain pattern SD1 to have the p-type. A concentration of the dopants of each of the buffer layer BFL and the main layer MAL may range from 1E18 atom/cm³ to 5E22 atom/cm³. The concentration of the dopants of the main layer MAL may be greater than the concentration of the dopants of the buffer layer BFL.

The buffer layer BFL may prevent a stacking fault between the substrate 100 (e.g., the first active pattern AP1) and the main layer MAL and between the main layer MAL and the first to third semiconductor patterns SP1, SP2 and SP3. When the stacking fault occurs, a channel resistance may be increased. The buffer layer BFL may protect the main layer MAL during a process of replacing second semiconductor layers SAL with first to third inner electrodes P01, P02 and P03 of a gate electrode GE. In other words, the buffer layer BFL may prevent an etching material of removing the second semiconductor layers SAL from permeating to the main layer MAL to etch it.

Each of the second source/drain patterns SD2 may include silicon (Si). The second source/drain pattern SD2 may further include dopants (e.g., phosphorus, arsenic, or antimony) for allowing the second source/drain pattern SD2 to have the n-type. A concentration of the dopants of the second source/drain pattern SD2 may range from 1E18 atom/cm³ to 5E22 atom/cm³.

Gate electrodes GE may extend in the first direction D1 to intersect the first and second channel patterns CH1 and CH2. The gate electrodes GE may be arranged in the second direction D2 at a first pitch. Each of the gate electrodes GE may vertically overlap with the first and second channel patterns CH1 and CH2.

The gate electrode GE may include a first inner electrode P01 between the active pattern AP1 or AP2 and the first semiconductor pattern SP1, a second inner electrode P02 between the first semiconductor pattern SP1 and the second semiconductor pattern SP2, a third inner electrode P03 between the second semiconductor pattern SP2 and the third semiconductor pattern SP3, and an outer electrode P04 on the third semiconductor pattern SP3.

Referring again to FIG. 5E, the gate electrode GE may be on a top surface TS, a bottom surface BS and both sidewalls SW of each of the first to third semiconductor patterns SP1, SP2 and SP3. In other words, a transistor according to the present embodiments may be a three-dimensional field effect transistor (e.g., a MBCFET or a GAAFET) in which the gate electrode GE three-dimensionally surrounds a channel.

In an implementation, the first single height cell SHC1 may have a first boundary BD1 and a second boundary BD2, which may be opposite to each other in the second direction D2. The first and second boundaries BD1 and BD2 may extend in the first direction D1. The first single height cell SHC1 may have a third boundary BD3 and a fourth boundary BD4, which may be opposite to each other in the first direction D1. The third and fourth boundaries BD3 and BD4 may extend in the second direction D2.

Gate cutting patterns CT may be on a boundary in the second direction D2 of each of the first and second single height cells SHC1 and SHC2. In an implementation, the gate cutting patterns CT may be on the third and fourth boundaries BD3 and BD4 of the first single height cell SHC1. The gate cutting patterns CT may be arranged along the third boundary BD3 at the first pitch. The gate cutting patterns CT may be arranged along the fourth boundary BD4 at the first pitch. The gate cutting patterns CT on the third and fourth boundaries BD3 and BD4 may overlap with the gate electrodes GE, respectively, when viewed in a plan view. The gate cutting patterns CT may include an insulating material such as silicon oxide, or silicon nitride.

The gate electrode GE on the first single height cell SHC1 may be separated from the gate electrode GE on the second single height cell SHC2 by the gate cutting pattern CT. The gate cutting pattern CT may be between the gate electrode GE on the first single height cell SHC1 and the gate electrode GE on the second single height cell SHC2, which may be aligned with each other in the first direction D1. In other words, the gate electrode GE extending in the first direction D1 may be divided into a plurality of the gate electrodes GE by the gate cutting patterns CT.

Referring again to FIGS. 4 and 5A to 5E, a pair of gate spacers GS may be on both sidewalls of the outer electrode P04 of the gate electrode GE, respectively. The gate spacers GS may extend along the gate electrode GE in the first direction D1. Top surfaces of the gate spacers GS may be higher than a top surface of the gate electrode GE. The top surfaces of the gate spacers GS may be coplanar with a top surface of a first interlayer insulating layer 110 to be described later. The gate spacers GS may include SiCN, SiCON, or SiN. For certain examples, each of the gate spacers GS may include a multi-layer formed of at least two of SiCN, SiCON, or SiN.

A gate capping pattern GP may be on the gate electrode GE. The gate capping pattern GP may extend along the gate electrode GE in the first direction D1. The gate capping pattern GP may include a material having an etch selectivity with respect to first and second interlayer insulating layers 110 and 120 to be described later. In an implementation, the gate capping pattern GP may include SiON, SiCN, SiCON, or SiN.

A gate insulating layer GI may be between the gate electrode GE and the first channel pattern CH1 and between the gate electrode GE and the second channel pattern CH2. The gate insulating layer GI may cover the top surface TS, the bottom surface BS and the both sidewalls SW of each of the first to third semiconductor patterns SP1, SP2 and SP3. The gate insulating layer GI may cover a top surface of the device isolation layer ST under the gate electrode GE.

In some embodiments, the gate insulating layer GI may include a silicon oxide layer, a silicon oxynitride layer, and/or a high-k dielectric layer. The high-k dielectric layer may include a high-k dielectric material of which a dielectric constant may be higher than that of a silicon oxide layer. In an implementation, the high-k dielectric material may include hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In certain embodiments, the semiconductor device may include a negative capacitance (NC) FET using a negative capacitor. In an implementation, the gate insulating layer GI may include a ferroelectric material layer having ferroelectric properties, and a paraelectric material layer having paraelectric properties.

The ferroelectric material layer may have a negative capacitance, and the paraelectric material layer may have a positive capacitance. In an implementation, when two or more capacitors are connected in series to each other and a capacitance of each of the capacitors has a positive value, a total capacitance may be reduced to be less than the capacitance of each of the capacitors. On the contrary, when capacitances of two or more capacitors connected in series to each other has a negative value, a total capacitance may have a positive value and may be greater than an absolute value of the capacitance of each of the capacitors.

When the ferroelectric material layer having the negative capacitance is connected in series to the paraelectric material layer having the positive capacitance, a total capacitance value of the ferroelectric and paraelectric material layers connected in series may increase. The transistor including the ferroelectric material layer may have a subthreshold swing (SS) less than 60 mV/decade at room temperature by using the increase in the total capacitance value.

The ferroelectric material layer may have the ferroelectric properties. In an implementation, the ferroelectric material layer may include hafnium oxide, hafnium zirconium oxide, barium strontium titanium oxide, barium titanium oxide, or lead zirconium titanium oxide. Here, for an example, the hafnium zirconium oxide may be a material formed by doping hafnium oxide with zirconium (Zr). For another example, the hafnium zirconium oxide may be a compound of hafnium (Hf), zirconium (Zr), and oxygen (O).

The ferroelectric material layer may further include dopants doped therein. In an implementation, the dopants may include aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). A kind of the dopants included in the ferroelectric material layer may be changed depending on a kind of the ferroelectric material included in the ferroelectric material layer.

When the ferroelectric material layer may include hafnium oxide, the dopants included in the ferroelectric material layer may include e.g., gadolinium (Gd), silicon (Si), zirconium (Zr), aluminum (Al), or yttrium (Y).

When the dopants are aluminum (Al), the ferroelectric material layer may include aluminum of 3 at % (atomic %) to 8 at %. Here, a ratio of the dopants may be a ratio of the amount of aluminum to a sum of the amounts of hafnium and aluminum.

When the dopants are silicon (Si), the ferroelectric material layer may include silicon of 2 at % to 10 at %. When the dopants are yttrium (Y), the ferroelectric material layer may include yttrium of 2 at % to 10 at %. When the dopants are gadolinium (Gd), the ferroelectric material layer may include gadolinium of 1 at % to 7 at %. When the dopants are zirconium (Zr), the ferroelectric material layer may include zirconium of 50 at % to 80 at %.

The paraelectric material layer may have the paraelectric properties. In an implementation, the paraelectric material layer may include silicon oxide or a metal oxide having a high-k dielectric constant. In an implementation, the metal oxide included in the paraelectric material layer may include hafnium oxide, zirconium oxide, or aluminum oxide.

The ferroelectric material layer and the paraelectric material layer may include the same material. The ferroelectric material layer may have the ferroelectric properties, but the paraelectric material layer may not have the ferroelectric properties. In an implementation, when the ferroelectric material layer and the paraelectric material layer include hafnium oxide, a crystal structure of hafnium oxide included in the ferroelectric material layer may be different from a crystal structure of hafnium oxide included in the paraelectric material layer.

The ferroelectric material layer may have a thickness showing the ferroelectric properties. In an implementation, the thickness of the ferroelectric material layer may range from 0.5 nm to 10 nm. A critical thickness showing the ferroelectric properties may be changed depending on a kind of a ferroelectric material, and thus the thickness of the ferroelectric material layer may be changed depending on a kind of the ferroelectric material included therein.

For some examples, the gate insulating layer GI may include a single ferroelectric material layer. For other examples, the gate insulating layer GI may include a plurality of the ferroelectric material layers spaced apart from each other. The gate insulating layer GI may have a stack structure in which the ferroelectric material layers and the paraelectric material layers may be alternately stacked.

The gate electrode GE may include a first metal pattern, and a second metal pattern on the first metal pattern. The first metal pattern may be on the gate insulating layer GI and may be adjacent to the first to third semiconductor patterns SP1, SP2 and SP3. The first metal pattern may include a work function metal of adjusting a threshold voltage of a transistor. A desired threshold voltage of the transistor may be obtained by adjusting a thickness and a composition of the first metal pattern. In an implementation, the first to third inner electrodes P01, P02 and P03 of the gate electrode GE may be formed of the first metal pattern corresponding to the work function metal.

The first metal pattern may include a metal nitride layer. In an implementation, the first metal pattern may include nitrogen (N) and a metal including titanium (Ti), tantalum (Ta), aluminum (Al), tungsten (W), or molybdenum (Mo). In addition, the first metal pattern may further include carbon (C). In some embodiments, the first metal pattern may include a plurality of stacked work function metal layers.

The second metal pattern may include a metal having a resistance lower than that of the first metal pattern. In an implementation, the second metal pattern may include tungsten (W), aluminum (Al), titanium (Ti), or tantalum (Ta). In an implementation, the outer electrode P04 of the gate electrode GE may include the first metal pattern and the second metal pattern on the first metal pattern.

Referring again to FIG. 5B, inner spacers IP may be on the first and second NMOSFET regions NR1 and NR2. In other words, the inner spacers IP may be on the second active pattern AP2. The inner spacers IP may be between the second source/drain pattern SD2 and the first to third inner electrodes P01, P02 and P03 of the gate electrode GE, respectively. The inner spacers IP may be in direct contact with the second source/drain pattern SD2. Each of the first to third inner electrodes P01, P02 and P03 of the gate electrode GE may be spaced apart from the second source/drain pattern SD2 by the inner spacer TP.

A first interlayer insulating layer 110 may be on the substrate 100. The first interlayer insulating layer 110 may cover the gate spacers GS and the first and second source/drain patterns SD1 and SD2. A top surface of the first interlayer insulating layer 110 may be substantially coplanar with the top surface of the gate capping pattern GP and the top surface of the gate spacer GS. A second interlayer insulating layer 120 covering the gate capping pattern GP may be on the first interlayer insulating layer 110. A third interlayer insulating layer 130 may be on the second interlayer insulating layer 120. A fourth interlayer insulating layer 140 may be on the third interlayer insulating layer 130. In an implementation, each of the first to fourth interlayer insulating layers 110 to 140 may include a silicon oxide layer.

A pair of isolation structures DB opposite to each other in the second direction D2 may be provided at both sides of each of the first and second single height cells SHC1 and SHC2. In an implementation, the pair of isolation structures DB may be on the first and second boundaries BD1 and BD2 of the first single height cell SHC1, respectively. The isolation structure DB may extend in the first direction D1 in parallel to the gate electrode GE. A pitch between the isolation structure DB and the gate electrode GE adjacent thereto may be equal to the first pitch.

The isolation structure DB may penetrate the first and second interlayer insulating layers 110 and 120 and may extend into the first and second active patterns AP1 and AP2. The isolation structure DB may penetrate an upper portion of each of the first and second active patterns AP1 and AP2. The isolation structure DB may electrically isolate an active region (e.g., the PMOSFET and NMOSFET regions) of each of the first and second single height cells SHC1 and SHC2 from an active region of another cell adjacent thereto.

Active contacts AC may penetrate the first and second interlayer insulating layers 110 and 120 electrically connected to the first and second source/drain patterns SD1 and SD2. A pair of the active contacts AC may be provided at both sides of the gate electrode GE, respectively. The active contact AC may have a bar shape extending in the first direction D1 when viewed in a plan view.

The active contact AC may be a self-aligned contact. In other words, the active contact AC may be self-aligned with the gate capping pattern GP and the gate spacer GS. In an implementation, the active contact AC may cover at least a portion of a sidewall of the gate spacer GS. The active contact AC may cover a portion of the top surface of the gate capping pattern GP.

Metal-semiconductor compound layers SC (e.g., silicide layers) may be between the active contact AC and the first source/drain pattern SD1 and between the active contact AC and the second source/drain pattern SD2, respectively. The active contact AC may be electrically connected to the source/drain pattern SD1 or SD2 through the metal-semiconductor compound layer SC. In an implementation, the metal-semiconductor compound layer SC may include titanium silicide, tantalum silicide, tungsten silicide, nickel silicide, or cobalt silicide.

Gate contacts GC may penetrate the second interlayer insulating layer 120 and the gate capping patterns GP electrically connected to the gate electrodes GE, respectively. Two gate contacts GC on the first single height cell SHC1 may overlap with the first PMOSFET region PR1 when viewed in a plan view. In other words, the two gate contacts GC on the first single height cell SHC1 may be on the first active pattern AP1 (see FIG. 5A). One gate contact GC on the first single height cell SHC1 may overlap with the first NMOSFET region NR1 when viewed in a plan view. In other words, the one gate contact GC on the first single height cell SHC1 may be on the second active pattern AP2 (see FIG. 5B).

The gate contact GC may be freely on the gate electrode GE regardless of its position. In an implementation, the gate contacts GC on the second single height cell SHC2 may be on the second PMOSFET region PR2, the second NMOSFET region NR2 and the device isolation layer ST filling the trench TR, respectively (see FIG. 4).

Referring to FIGS. 5A and 5D, an upper portion of the active contact AC adjacent to the gate contact GC may be filled with an upper insulating pattern UIP. A bottom surface of the upper insulating pattern UIP may be lower than a bottom surface of the gate contact GC. In other words, a top surface of the active contact AC adjacent to the gate contact GC may be lower than the bottom surface of the gate contact GC due to the upper insulating pattern UIP. Thus, it is possible to prevent an electrical short between the gate contact GC and the active contact AC adjacent thereto. In an implementation, the upper insulating pattern UIP may include a silicon-based insulating material (e.g., silicon oxide, silicon nitride, or silicon oxynitride).

Each of the active contact AC and the gate contact GC may include a conductive pattern FM and a barrier pattern BM surrounding the conductive pattern FM. In an implementation, the conductive pattern FM may include aluminum, copper, tungsten, molybdenum, or cobalt. The barrier pattern BM may cover sidewalls and a bottom surface of the conductive pattern FM. The barrier pattern BM may include a metal layer/a metal nitride layer. The metal layer may include titanium, tantalum, tungsten, nickel, cobalt, or platinum. The metal nitride layer may include a titanium nitride (TiN) layer, a tantalum nitride (TaN) layer, a tungsten nitride (WN) layer, a nickel nitride (NiN) layer, a cobalt nitride (CoN) layer, or a platinum nitride (PtN) layer.

Referring again to FIGS. 4 and 5C to 5E, first to third lower power interconnection lines VPR1, VPR2 and VPR3 may be provided in a lower portion of the substrate 100. The first to third lower power interconnection lines VPR1, VPR2 and VPR3 may extend in the second direction D2 in parallel to each other. The first lower power interconnection line VPR1 may be on the fourth boundary BD4 of the first single height cell SHC1. The second lower power interconnection line VPR2 may be on the third boundary BD3 of the first single height cell SHC1. In other words, the first single height cell SHC1 may be defined between the first lower power interconnection line VPR1 and the second lower power interconnection line VPR2. The second single height cell SHC2 may be defined between the second lower power interconnection line VPR2 and the third lower power interconnection line VPR3.

Referring again to FIGS. 5C and 5D, representatively, the second lower power interconnection line VPR2 may be electrically connected to an upper contact UCT. The upper contact UCT may electrically connect the second lower power interconnection line VPR2 to a corresponding one of the active contacts AC. More particularly, the upper contact UCT may be connected directly to the corresponding active contact AC. Each of the lower power interconnection lines VPR1 to VPR3 may be electrically connected to corresponding one(s) of the source/drain patterns SD1 and SD2 through a corresponding one of the upper contacts UCT and a corresponding one of the active contacts AC.

The upper contacts UCT and the lower power interconnection lines VPR1 to VPR3 may include the same metal or different metals. In an implementation, the lower power interconnection lines VPR1 to VPR3 may include copper or tungsten. The upper contact UCT may include copper, molybdenum, tungsten, or ruthenium. A lower portion of each of the upper contacts UCT may be surrounded by a corresponding one of the lower power interconnection lines VPR1 to VPR3. This will be described later in more detail with reference to FIG. 6.

A width (or a diameter) of the upper contact UCT may increase toward the third direction D3. In other words, the width of the upper contact UCT may become progressively less toward a bottom surface 100b of the substrate 100. Meanwhile, a line width of each of the lower power interconnection lines VPR1 to VPR3 may become progressively greater toward the bottom surface 100b of the substrate 100.

A first liner LIN1 may be on a sidewall of the upper contact UCT. The first liner LIN1 may function as a spacer of the upper contact UCT. The first liner LIN1 may include a silicon-based insulating material (e.g., silicon oxide, silicon nitride, or silicon oxynitride).

A lower spacer LSP may be on a sidewall of each of the lower power interconnection lines VPR1 to VPR3. Each of the lower power interconnection lines VPR1 to VPR3 may be electrically insulated from the substrate 100 by the lower spacer LSP. The lower spacer LSP may include a second liner LIN2 and an oxide spacer OSP. The second liner LIN2 and the oxide spacer OSP may include different insulating materials. The second liner LIN2 may include a silicon-based insulating material which is the same as or different from that of the first liner LIN1. The oxide spacer OSP may include silicon oxide.

If the oxide spacer OSP is omitted, a leakage current from the lower power interconnection lines VPR1 to VPR3 to the substrate 100 may be increased. The line width of each of the lower power interconnection lines VPR1 to VPR3 may be reduced to reduce the leakage current, and in this case, electrical characteristics of a semiconductor device may be deteriorated.

On the contrary, the oxide spacer OSP may effectively prevent a leakage current from the lower power interconnection lines VPR1 to VPR3 to the substrate 100. Since the leakage current may be prevented by the oxide spacer OSP, the line widths of the lower power interconnection lines VPR1 to VPR3 may be increased. Thus, a resistivity of the lower power interconnection lines VPR1 to VPR3 may be reduced. Process defects caused by misalignment between each of the lower power interconnection lines VPR1 to VPR3 and the upper contact UCT may be reduced or minimized. A contact resistance between each of the lower power interconnection lines VPR1 to VPR3 and the upper contact UCT may be reduced. As a result, the embodiments may improve reliability and electrical characteristics of the semiconductor device.

Bottom surfaces of the lower power interconnection lines VPR1 to VPR3 may be coplanar with the bottom surface 100b of the substrate 100. A power delivery network layer PDN may be on the bottom surface 100b of the substrate 100. The power delivery network layer PDN may include a plurality of lower interconnection lines electrically connected to the first to third lower power interconnection lines VPR1, VPR2 and VPR3. In an implementation, the power delivery network layer PDN may include an interconnection network for applying a source voltage VSS to the first and third lower power interconnection lines VPR1 and VPR3. The power delivery network layer PDN may include an interconnection network for applying a drain voltage VDD to the second lower power interconnection line VPR2.

A first metal layer M1 may be provided in the third interlayer insulating layer 130. The first metal layer M1 may include first interconnection lines M1_I. The first interconnection lines M1_I of the first metal layer M1 may extend in the second direction D2 in parallel to each other.

Power interconnection lines for supplying power to the single height cell SHC may be buried in the substrate 100 in the form of the lower power interconnection lines VPR1 to VPR3. Thus, the power interconnection lines may be omitted in the first metal layer M1. The first interconnection lines M1_I for transmitting signals may be in the first metal layer M1.

The first metal layer M1 may further include first vias VI1. The first vias VI1 may be provided under the first interconnection lines M1_I of the first metal layer M1. At least one of the active contacts AC may be electrically connected to a corresponding one of the first interconnection lines M1_I of the first metal layer M1 through a corresponding one of the first vias VI1. The gate contact GC may be electrically connected to a corresponding one of the first interconnection lines M1_I of the first metal layer M1 through a corresponding one of the first vias VI1.

The first interconnection line M1_I of the first metal layer M1 and the first via VI1 thereunder may be formed using different processes. In other words, each of the first interconnection line M1_I and the first via VI1 of the first metal layer M1 may be formed using a single damascene process. The semiconductor device according to the present embodiments may be formed using processes less than 20 nm.

A second metal layer M2 may be provided in the fourth interlayer insulating layer 140. The second metal layer M2 may include a plurality of second interconnection lines M2_I. Each of the second interconnection lines M2_I of the second metal layer M2 may have a line shape or bar shape extending in the first direction D1. In other words, the second interconnection lines M2_I may extend in the first direction D1 in parallel to each other.

The second metal layer M2 may further include second vias VI2 provided under the second interconnection lines M2_I. The first interconnection line M1_I of the first metal layer M1 may be electrically connected to a corresponding one of the second interconnection lines M2_I of the second metal layer M2 through a corresponding one of the second vias VI2. In an implementation, the second interconnection line M2_I of the second metal layer M2 and the second via VI2 thereunder may be formed using a dual damascene process together.

The first interconnection line M1_I of the first metal layer M1 and the second interconnection line M2_I of the second metal layer M2 may include the same conductive material or different conductive materials. In an implementation, each of the first and second interconnection lines M1_I and M2_I of the first and second metal layers M1 and M2 may include aluminum, copper, tungsten, molybdenum, ruthenium, or cobalt. Metal layers (e.g., M3, M4, M5, . . . ) stacked on the fourth interlayer insulating layer 140 may be additionally provided. Each of the stacked metal layers may include interconnection lines for routing between cells.

Referring to FIG. 6, representatively, the second lower power interconnection line VPR2 may include a connection portion CNP corresponding to its upper portion. A lower portion of the upper contact UCT may protrude into the connection portion CNP. The connection portion CNP may be in direct contact with the lower portion of the upper contact UCT. The connection portion CNP may be in direct contact with a bottom surface BOS and both sidewalls SIS of the lower portion of the upper contact UCT.

A lower portion of the connection portion CNP may have a first width WI1, a central portion of the connection portion CNP may have a second width WI2, and an upper portion of the connection portion CNP may have a third width WI3. The first width WI1 may be greater than the second width WI2, and the third width WI3 may be greater than the second width WI2. In other words, the connection portion CNP may have a sandglass (e.g., hourglass) shape. The shape of the connection portion CNP may be defined by a profile of the oxide spacer OSP. The oxide spacer OSP according to the present embodiments may not have a uniform (or conformal) thickness.

An uppermost portion of the connection portion CNP may include a protrusion PRP. The protrusion PRP may be between the lower portion of the upper contact UCT and the second liner LIN2. The protrusion PRP may extend in the third direction D3 toward the first liner LIN1. A contact area between the second lower power interconnection line VPR2 and the upper contact UCT may be increased by the protrusion PRP. In other words, a contact resistance between the second lower power interconnection line VPR2 and the upper contact UCT may be reduced by the protrusion PRP.

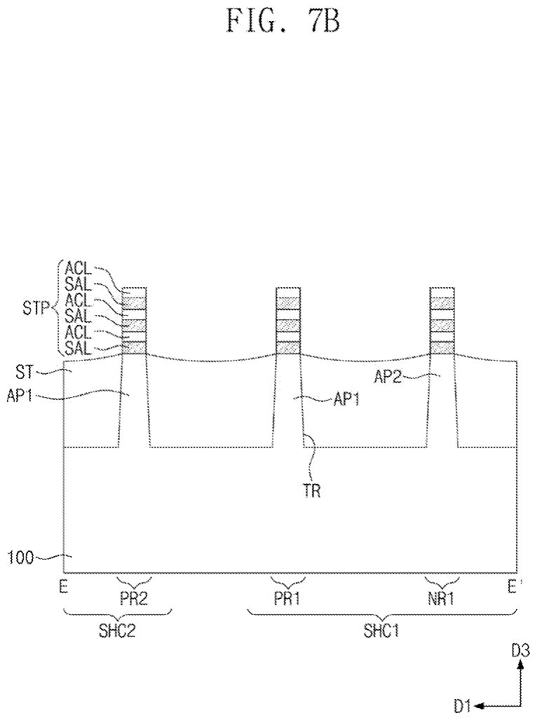

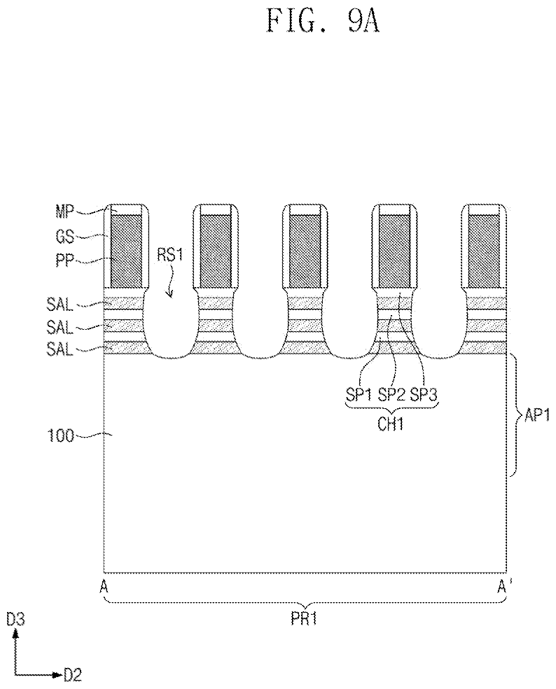

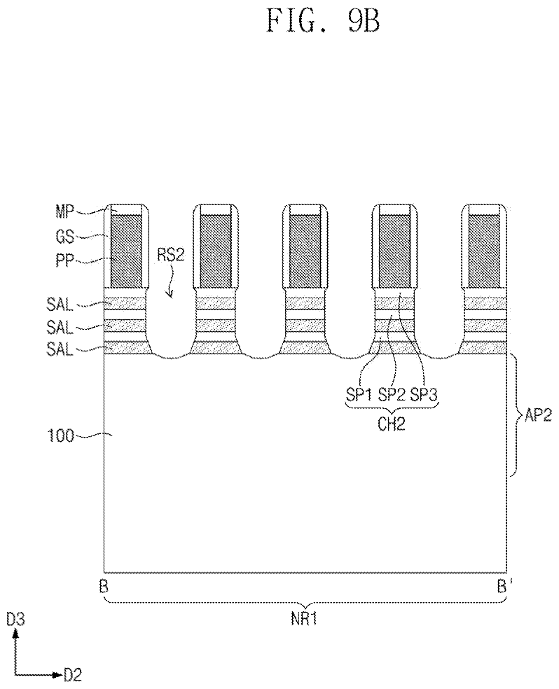

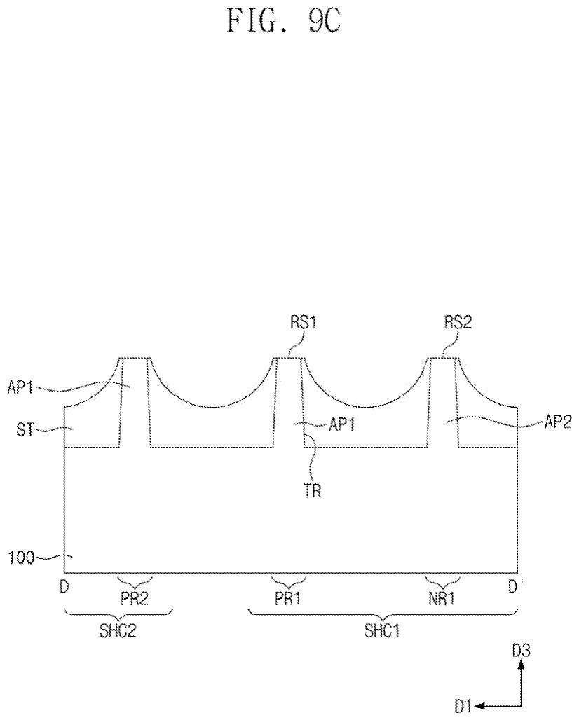

FIGS. 7A to 17 are cross-sectional views of a method of manufacturing a semiconductor device according to example embodiments. More particularly, FIGS. 7A, 8A, 9A, 10A, 11A and 12A are cross-sectional views corresponding to the line A-A′ of FIG. 4. FIGS. 9B, 10B, 11B and 12B are cross-sectional views corresponding to the line B-B′ of FIG. 4. FIGS. 9C, 10C and 12C are cross-sectional views corresponding to the line D-D′ of FIG. 4. FIGS. 7B, 8B, 11C and 12D are cross-sectional views corresponding to the line E-E′ of FIG. 4.

Referring to FIGS. 7A and 7B, a substrate 100 including first and second PMOSFET regions PR1 and PR2 and first and second NMOSFET regions NR1 and NR2 may be provided. First semiconductor layers ACL and second semiconductor layers SAL may be alternately on the substrate 100. The first semiconductor layers ACL may include one of silicon (Si), germanium (Ge) or silicon-germanium (SiGe), and the second semiconductor layers SAL may include another of silicon (Si), germanium (Ge) or silicon-germanium (SiGe).

The second semiconductor layer SAL may include a material having an etch selectivity with respect to the first semiconductor layer ACL. In an implementation, the first semiconductor layers ACL may include silicon (Si), and the second semiconductor layers SAL may include silicon-germanium (SiGe). A concentration of germanium (Ge) of each of the second semiconductor layers SAL may range from 10 at % to 30 at %.

Mask patterns may be on the first and second PMOSFET regions PR1 and PR2 and the first and second NMOSFET regions NR1 and NR2 of the substrate 100, respectively. Each of the mask patterns may have a line shape or bar shape extending in the second direction D2.

A patterning process may be performed using the mask patterns as etch masks to form a trench TR defining a first active pattern AP1 and a second active pattern AP2. The first active pattern AP1 may be on each of the first and second PMOSFET regions PR1 and PR2. The second active pattern AP2 may be on each of the first and second NMOSFET regions NR1 and NR2. The first and second active patterns AP1 and AP2 may have line shapes extending in the second direction D2 in parallel to each other when viewed in a plan view.

A stack pattern STP may be on each of the first and second active patterns AP1 and AP2. The stack pattern STP may include the first semiconductor layers ACL and the second semiconductor layers SAL, which may be alternately stacked. The stack patterns STP may be formed together with the first and second active patterns AP1 and AP2 in the patterning process.

A device isolation layer ST filling the trench TR may be formed. In an implementation, an insulating layer covering the first and second active patterns AP1 and AP2 and the stack patterns STP may be on an entire top surface of the substrate 100. The insulating layer may be recessed until the stack patterns STP are exposed, thereby forming the device isolation layer ST.

The device isolation layer ST may include an insulating material (e.g., silicon oxide). The stack patterns STP may be exposed above the device isolation layer ST. In other words, the stack patterns STP may vertically protrude above the device isolation layer ST.

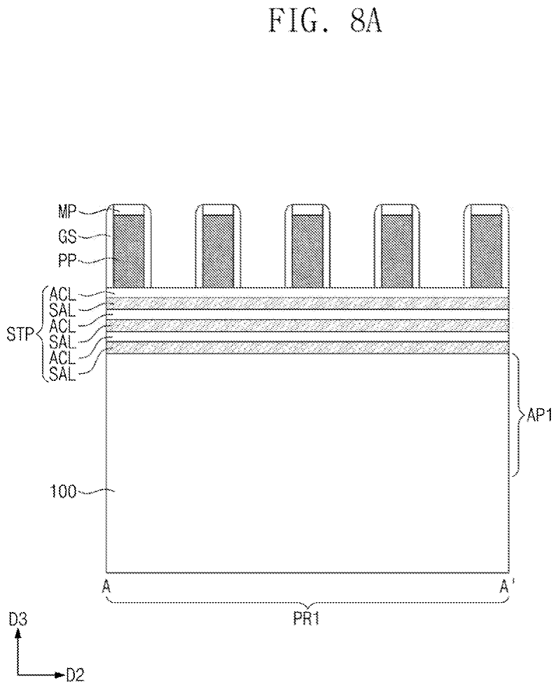

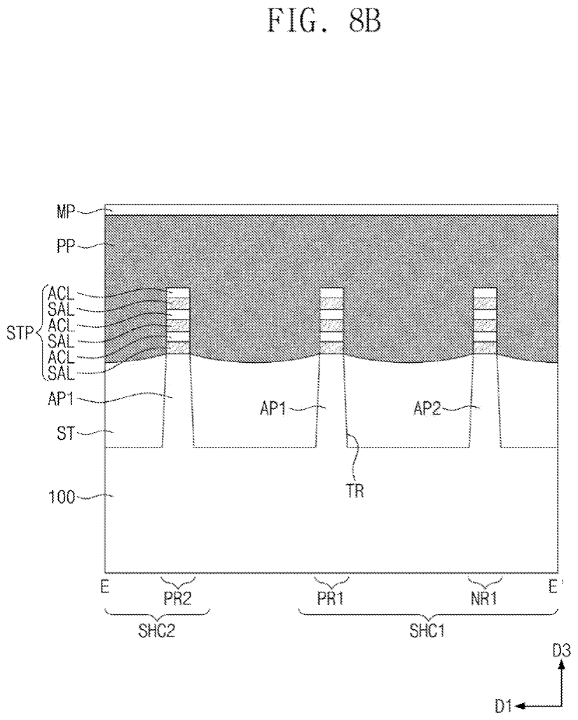

Referring to FIGS. 8A and 8B, sacrificial patterns PP intersecting the stack patterns STP may be on the substrate 100. Each of the sacrificial patterns PP may have a line shape or bar shape extending in the first direction D1. The sacrificial patterns PP may be arranged at a first pitch in the second direction D2.

In an implementation, the formation of the sacrificial patterns PP may include forming a sacrificial layer on an entire top surface of the substrate 100, forming hard mask patterns MP on the sacrificial layer, and patterning the sacrificial layer using the hard mask patterns MP as etch masks. The sacrificial layer may include poly-silicon.

A pair of gate spacers GS may be on both sidewalls of each of the sacrificial patterns PP, respectively. The formation of the gate spacers GS may include conformally forming a gate spacer layer on an entire top surface of the substrate 100, and anisotropically etching the gate spacer layer. The gate spacer layer may include SiCN, SiCON, or SiN. In certain embodiments, the gate spacer layer may be a multi-layer including at least two of SiCN, SiCON, or SiN.

Referring to FIGS. 9A to 9C, first recesses RS1 may be in the stack pattern STP on the first active pattern AP1. Second recesses RS2 may be in the stack pattern STP on the second active pattern AP2. The device isolation layer ST at both sides of each of the first and second active patterns AP1 and AP2 may be further recessed during the formation of the first and second recesses RS1 and RS2 (see FIG. 9C).

More particularly, the stack pattern STP on the first active pattern AP1 may be etched using the hard mask patterns MP and the gate spacers GS as etch masks to form the first recesses RS1. The first recess RS1 may be between a pair of the sacrificial patterns PP. The second recesses RS2 in the stack pattern STP on the second active pattern AP2 may be formed by the same method as the first recesses RS1.

First to third semiconductor patterns SP1, SP2 and SP3 stacked sequentially may be formed from the first semiconductor layers ACL between the first recesses RS1 adjacent to each other. First to third semiconductor patterns SP1, SP2 and SP3 stacked sequentially may be formed from the first semiconductor layers ACL between the second recesses RS2 adjacent to each other. The first to third semiconductor patterns SP1, SP2 and SP3 between the first recesses RS1 adjacent to each other may constitute a first channel pattern CH1. The first to third semiconductor patterns SP1, SP2 and SP3 between the second recesses RS2 adjacent to each other may constitute a second channel pattern CH2.

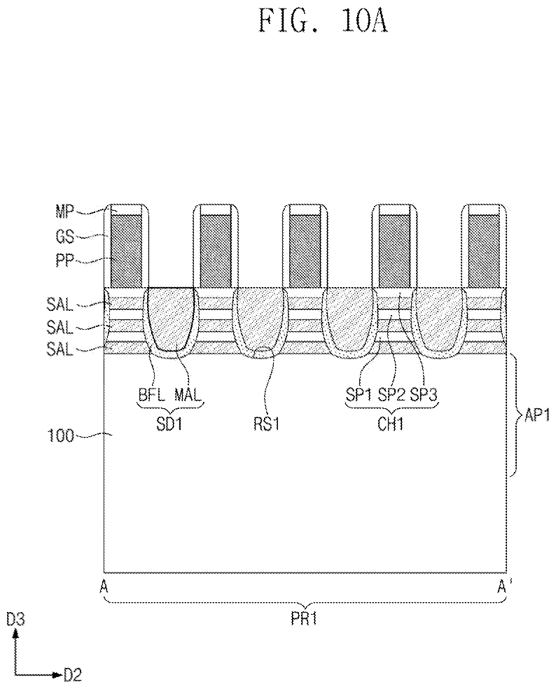

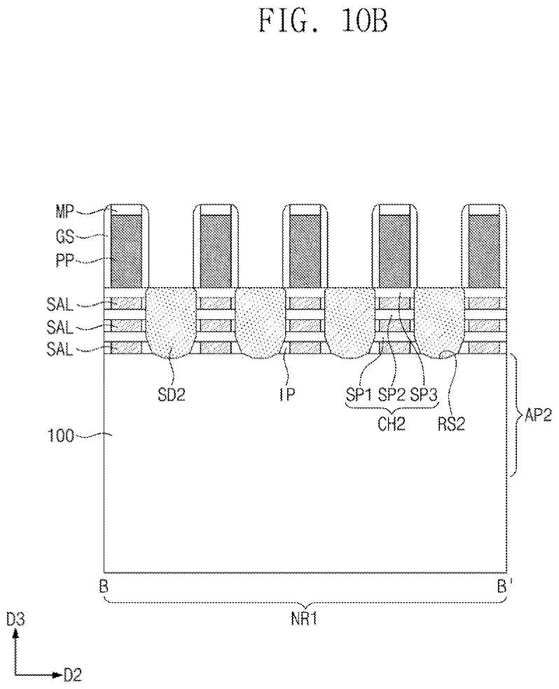

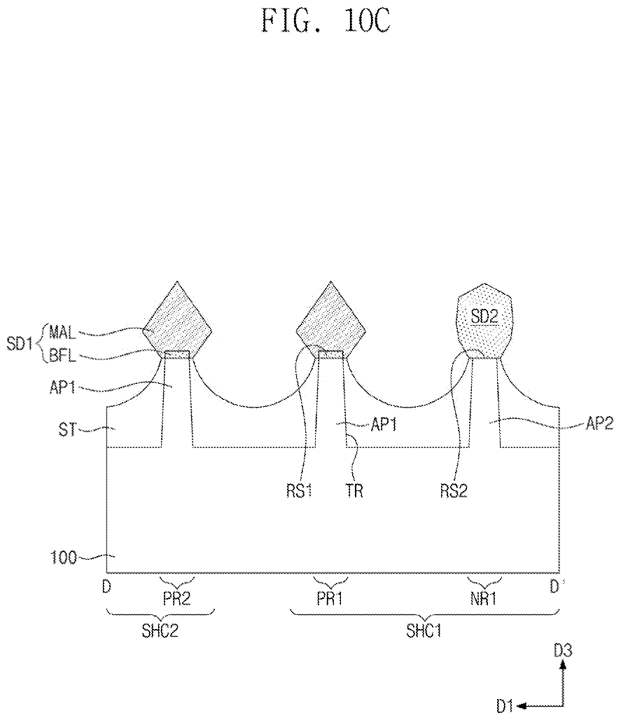

Referring to FIGS. 10A to 10C, first source/drain patterns SD1 may be in the first recesses RS1, respectively. In an implementation, a first selective epitaxial growth (SEG) process may be performed using an inner surface of the first recess RS1 as a seed layer to form a buffer layer BFL. The buffer layer BFL may be grown using the first to third semiconductor patterns SP1, SP2 and SP3 and the substrate 100 exposed by the first recess RS1 as a seed. In an implementation, the first SEG process may include a chemical vapor deposition (CVD) process or a molecular beam epitaxy (MBE) process.

The buffer layer BFL may include a semiconductor element (e.g., SiGe) of which a lattice constant may be greater than a lattice constant of a semiconductor element of the substrate 100. The buffer layer BFL may contain a relatively low concentration of germanium (Ge). The buffer layer BFL may contain silicon (Si) except germanium (Ge). A concentration of germanium (Ge) of the buffer layer BFL may range from 0 at % to 10 at %.

A second SEG process may be performed on the buffer layer BFL to form a main layer MAL. The main layer MAL may completely or almost fill the first recess RS1. The main layer MAL may contain a relatively high concentration of germanium (Ge). In an implementation, a concentration of germanium (Ge) of the main layer MAL may range from 30 at % to 70 at %.

A third SEG process may be performed on the main layer MAL to form a capping layer. The capping layer may include silicon (Si). A concentration of silicon (Si) of the capping layer may range from 98 at % to 100 at %.

Dopants (e.g., boron, gallium or indium) for allowing the first source/drain pattern SD1 to have a p-type may be injected in-situ during the formation of the buffer layer BFL and the main layer MAL. Alternatively, after the formation of the first source/drain pattern SD1, the dopants may be injected or implanted into the first source/drain pattern SD1.

Second source/drain patterns SD2 may be in the second recesses RS2, respectively. In an implementation, the second source/drain pattern SD2 may be formed by performing a SEG process using an inner surface of the second recess RS2 as a seed layer. In an implementation, the second source/drain pattern SD2 may include the same semiconductor element (e.g., Si) as the substrate 100.

Dopants (e.g., phosphorus, arsenic or antimony) for allowing the second source/drain pattern SD2 to have an n-type may be injected in-situ during the formation of the second source/drain pattern SD2. Alternatively, after the formation of the second source/drain pattern SD2, the dopants may be injected or implanted into the second source/drain pattern SD2.

Before the formation of the second source/drain pattern SD2, portions of the second semiconductor layers SAL exposed by the second recess RS2 may be replaced with an insulating material to form inner spacers IP. As a result, the inner spacers IP may be between the second source/drain pattern SD2 and the second semiconductor layers SAL, respectively.

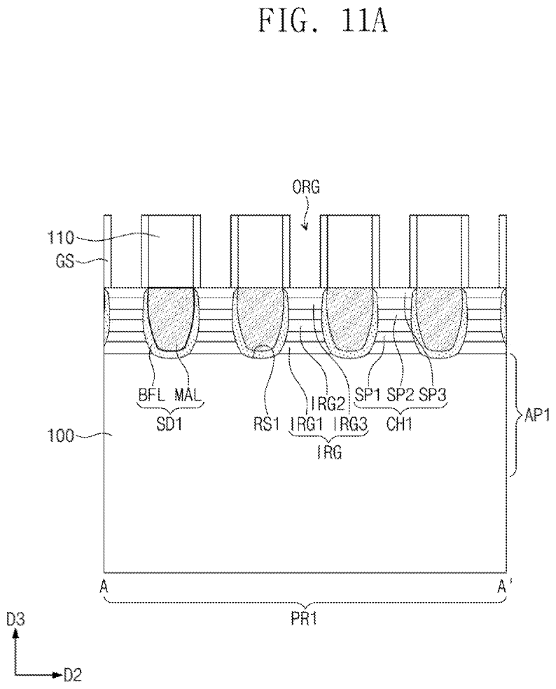

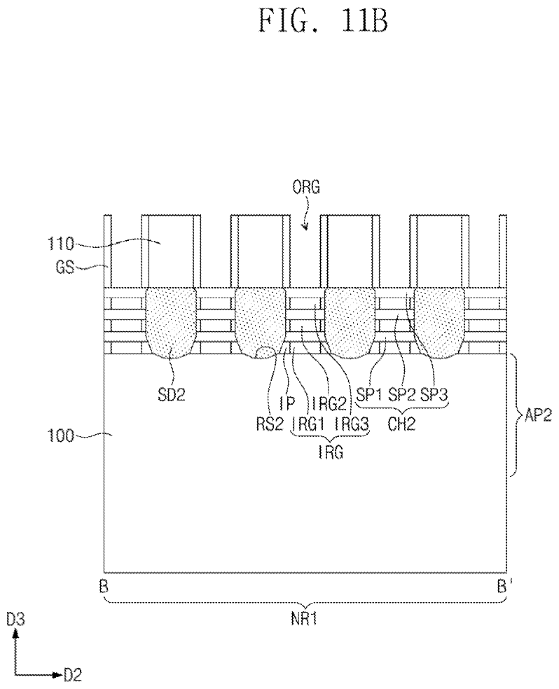

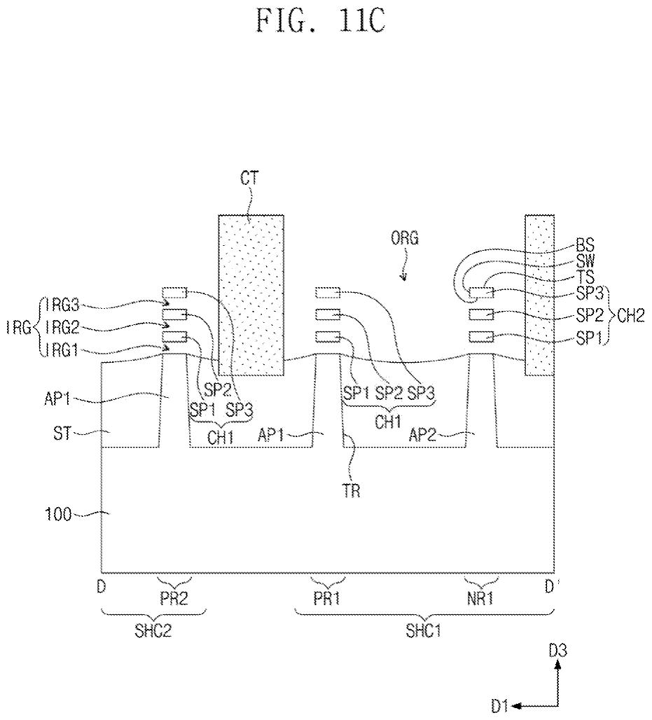

Referring to FIGS. 11A to 11C, a first interlayer insulating layer 110 may cover the first and second source/drain patterns SD1 and SD2, the hard mask patterns MP and the gate spacers GS. In an implementation, the first interlayer insulating layer 110 may include a silicon oxide layer.

The first interlayer insulating layer 110 may be planarized to expose top surfaces of the sacrificial patterns PP. The planarization of the first interlayer insulating layer 110 may be performed using an etch-back process or a chemical mechanical polishing (CMP) process. The hard mask patterns MP may be completely removed during the planarization process. As a result, a top surface of the first interlayer insulating layer 110 may be substantially coplanar with the top surfaces of the sacrificial patterns PP and top surfaces of the gate spacers GS.

A region of the sacrificial pattern PP may be selectively opened using a photolithography process. In an implementation, regions of the sacrificial pattern PP on the third and fourth boundaries BD3 and BD4 of the first single height cell SHC1 may be selectively opened. The opened region of the sacrificial pattern PP may be selectively etched and thus may be removed. A space formed by the removal of the sacrificial pattern PP may be filled with an insulating material to form a gate cutting pattern CT (see FIG. 11C).

Remaining exposed portions of the sacrificial patterns PP may be selectively removed. An outer region ORG exposing the first and second channel patterns CH1 and CH2 may be formed by the removal of the sacrificial pattern PP (see FIG. 11C). The removal of the sacrificial patterns PP may include performing a wet etching process using an etching solution capable of selectively etching poly-silicon.

The second semiconductor layers SAL exposed through the outer region ORG may be selectively removed to form inner regions IRG (see FIG. 11C). In an implementation, an etching process of selectively etching the second semiconductor layers SAL may be performed to remove the second semiconductor layers SAL while leaving the first to third semiconductor patterns SP1, SP2 and SP3. The etching process may have a high etch rate with respect to silicon-germanium having a relatively high germanium concentration. In an implementation, the etching process may have a high etch rate with respect to silicon-germanium having a germanium concentration greater than 10 at %.

The second semiconductor layers SAL on the first and second PMOSFET regions PR1 and PR2 and the first and second NMOSFET regions NR1 and NR2 may be completely removed during the etching process. The etching process may be a wet etching process. An etching material used in the etching process may quickly remove the second semiconductor layer SAL having a relatively high germanium concentration. Meanwhile, the first source/drain patterns SD1 on the first and second PMOSFET regions PR1 and PR2 may be protected by the buffer layer BFL having a relatively low germanium concentration during the etching process.

Referring again to FIG. 11C, since the second semiconductor layers SAL may be selectively removed, the stacked first to third semiconductor patterns SP1, SP2 and SP3 may remain on each of the first and second active patterns AP1 and AP2. First to third inner regions IRG1, IRG2 and IRG3 may be formed by the removal of the second semiconductor layers SAL. The first inner region IRG1 may be between the active pattern AP1 or AP2 and the first semiconductor pattern SP1, the second inner region IRG2 may be between the first semiconductor pattern SP1 and the second semiconductor pattern SP2, and the third inner region IRG3 may be between the second semiconductor pattern SP2 and the third semiconductor pattern SP3.

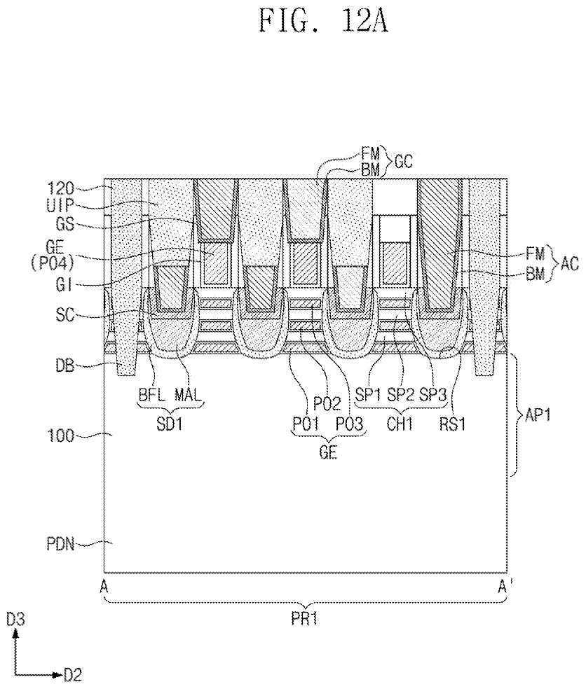

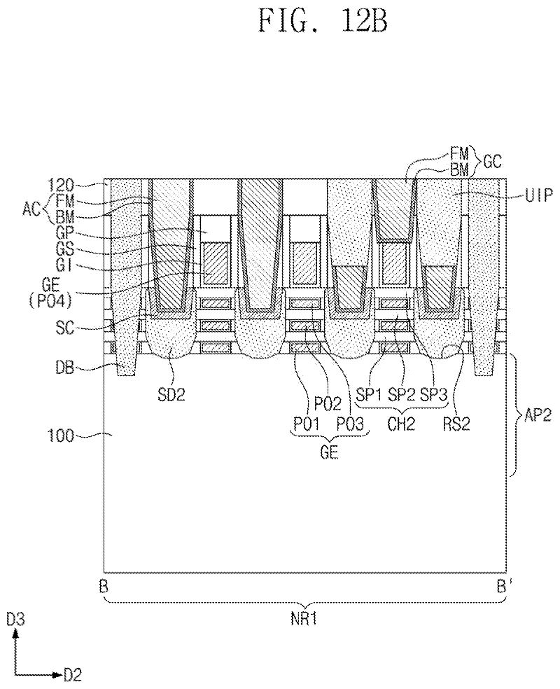

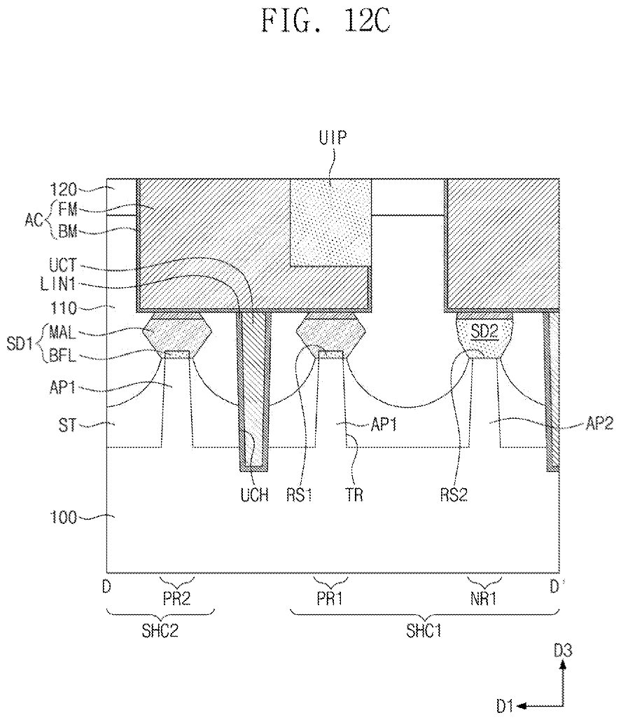

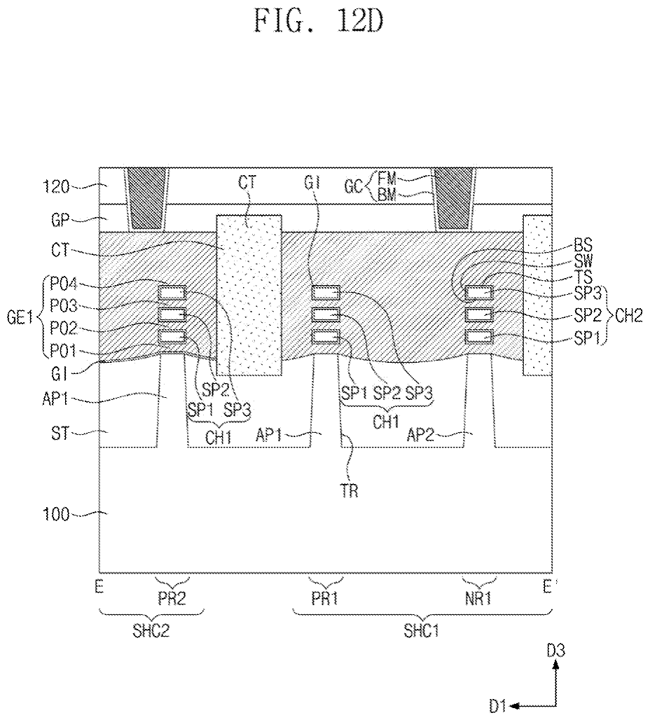

Referring to FIGS. 12A to 12D, a gate insulating layer GI may be conformally on the exposed first to third semiconductor patterns SP1, SP2 and SP3. A gate electrode GE may be on the gate insulating layer GI. The gate electrode GE may include first to third inner electrodes P01, P02 and P03 in the first to third inner regions IRG1, IRG2 and IRG3, respectively, and an outer electrode P04 in the outer region ORG.

The gate electrode GE may be recessed to reduce its height. Upper portions of the gate cutting patterns CT may also be slightly recessed during the recessing of the gate electrode GE. A gate capping pattern GP may be on the recessed gate electrode GE.

A second interlayer insulating layer 120 may be on the first interlayer insulating layer 110. The second interlayer insulating layer 120 may include a silicon oxide layer. An upper contact hole UCH may vertically extend from the second interlayer insulating layer 120 to the substrate 100. In an implementation, the upper contact hole UCH may be between the first single height cell SHC1 and the second single height cell SHC2. The upper contact hole UCH may be between a pair of the first source/drain patterns SD1 adjacent to each other. A bottom of the upper contact hole UCH may be lower than a bottom surface of the device isolation layer ST. The upper contact hole UCH may expose an upper portion of the substrate 100.

A first liner LIN1 may be conformally formed in the upper contact hole UCH. The first liner LIN1 may partially fill the upper contact hole UCH. The first liner LIN1 may be a silicon-based insulating material (e.g., silicon oxide, silicon nitride, or silicon oxynitride). An upper contact UCT completely filling the upper contact hole UCH may be on the first liner LIN1. The upper contact UCT may be a metal (e.g., copper, molybdenum, tungsten, or ruthenium).

Active contacts AC may penetrate the second interlayer insulating layer 120 and the first interlayer insulating layer 110, and the active contacts AC may be electrically connected to the first and second source/drain patterns SD1 and SD2. A gate contact GC may penetrate the second interlayer insulating layer 120 and the gate capping pattern GP, and the gate contact GC may be electrically connected to the gate electrode GE.

Referring to FIG. 12C, at least one of the active contacts AC may vertically overlap with the upper contact UCT. Thus, a top surface of the upper contact UCT may be in direct contact with a bottom surface of a corresponding one of the active contacts AC.

The formation of each of the active contact AC and the gate contact GC may include forming a barrier pattern BM and forming a conductive pattern FM on the barrier pattern BM. The barrier pattern BM may be conformally formed and may include a metal layer/a metal nitride layer. The conductive pattern FM may include a low-resistance metal.

A pair of isolation structures DB may be formed at both sides of each of the first and second single height cells SHC1 and SHC2. The isolation structure DB may penetrate the second interlayer insulating layer 120 and the gate electrode GE and may extend into the active pattern AP1 or AP2. The isolation structure DB may include an insulating material such as silicon oxide or silicon nitride.

Referring again to FIGS. 4 and 5A to 5E, a third interlayer insulating layer 130 may be on the upper contacts UCT, the active contacts AC and the gate contacts GC. A first metal layer M1 may be in the third interlayer insulating layer 130. The first metal layer M1 may include a first interconnection line M1_I electrically connected to at least one of the active contacts AC and the gate contacts GC. A fourth interlayer insulating layer 140 may be on the third interlayer insulating layer 130. A second metal layer M2 may be in the fourth interlayer insulating layer 140.

Lower power interconnection lines VPR1 to VPR3 may be in a lower portion of the substrate 100. Each of the lower power interconnection lines VPR1 to VPR3 may be electrically connected to a corresponding one of the active contacts AC through a corresponding one of the upper contacts UCT. A power delivery network layer PDN may be on a bottom surface 100b of the substrate 100. The power delivery network layer PDN may apply a source voltage or a drain voltage to each of the lower power interconnection lines VPR1 to VPR3.

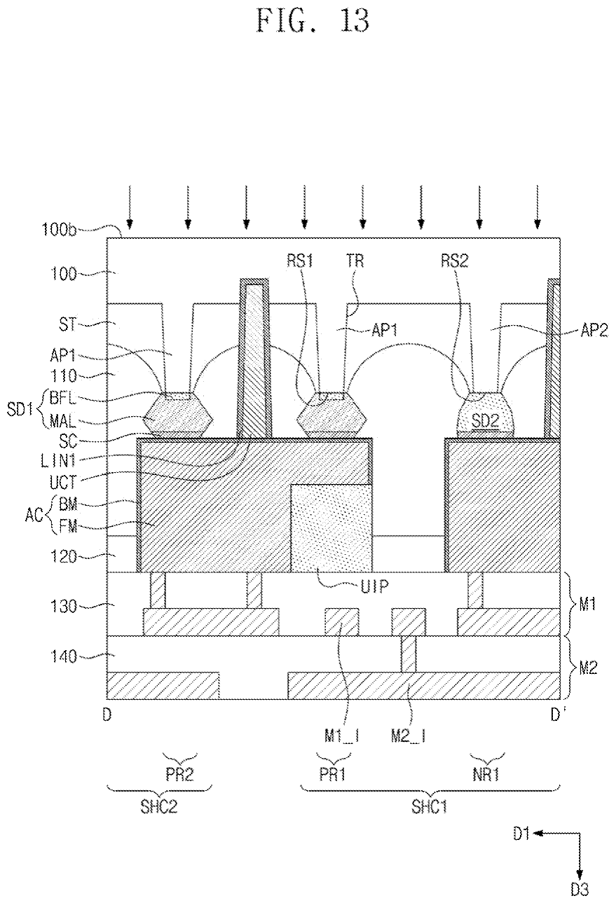

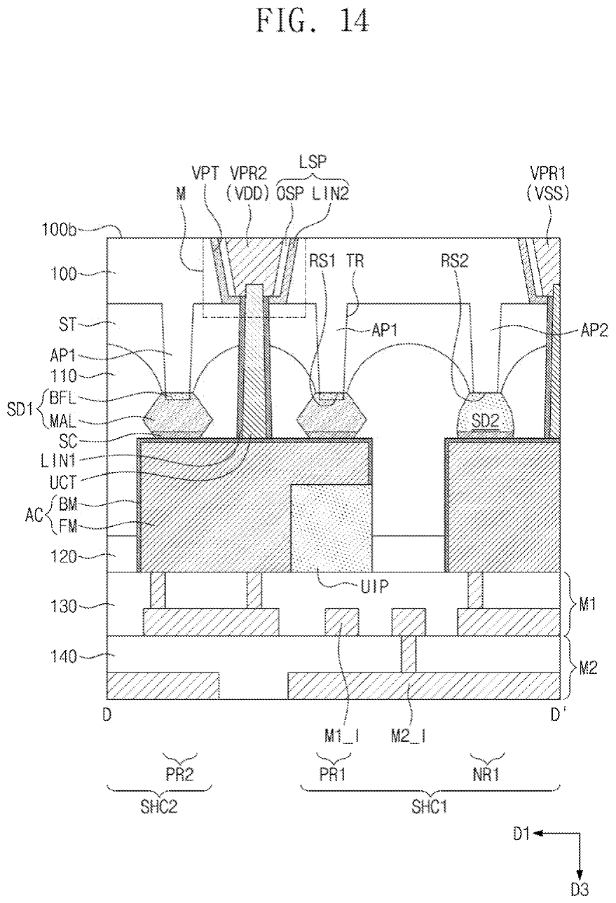

FIGS. 13 and 14 are cross-sectional views illustrating a method of forming the lower power interconnection line of FIG. 5D. Referring to FIG. 13, after a BEOL process is completed, the substrate 100 may be turned over to expose the bottom surface 100b of the substrate 100. A planarization process may be performed on the bottom surface 100b of the substrate 100 to reduce a thickness of the substrate 100.

Referring to FIG. 14, a patterning process may be performed on the bottom surface 100b of the substrate 100 to form a plurality of lower interconnection line trenches VPT. Each of the lower interconnection line trenches VPT may expose the first liner LIN1. In other words, the lower interconnection line trench VPT may be aligned with the upper contact UCT. The lower interconnection line trench VPT may have a line shape extending in the second direction D2.

A lower spacer LSP may be in the lower interconnection line trench VPT. The lower spacer LSP may include a second liner LIN2 and an oxide spacer OSP. The lower interconnection line trenches VPT may be filled with a conductive material to form the lower power interconnection lines VPR1 to VPR3 electrically connected to the upper contacts UCT. Thereafter, the power delivery network layer PDN may be on the bottom surface 100b of the substrate 100.

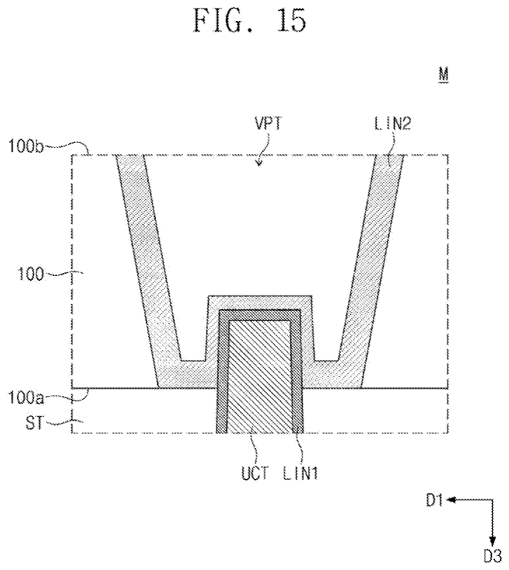

The process of forming the lower spacer LSP and the lower power interconnection line VPR1, VPR2 or VPR3 will be described in more detail with reference to FIGS. 15 to 17. Referring to FIG. 15, the second liner LIN2 may be in the lower interconnection line trench VPT. The second liner LIN2 may be a silicon-based insulating material (e.g., silicon nitride) which may be the same as or different from that of the first liner LIN1. The second liner LIN2 may directly cover the first liner LIN1 protruding into the lower interconnection line trench VPT.

Referring to FIG. 16, an oxide layer (e.g., a silicon oxide layer) may fill the lower interconnection line trench VPT. A mask having an opening vertically overlapping with the upper contact UCT may be on the oxide layer. The mask may be formed using a photolithography process. The oxide layer in the lower interconnection line trench VPT may be etched using the mask as an etch mask. Thus, the oxide spacer OSP may be on an inner sidewall of the lower interconnection line trench VPT.

The second liner LIN2 and the oxide spacer OSP may constitute the lower spacer LSP. The lower spacer LSP may have a double-layered structure. The exposed second liner LIN2 may be selectively etched using the oxide spacer OSP as an etch mask. Thus, a topmost surface of the first liner LIN1 may be exposed through the lower interconnection line trench VPT.

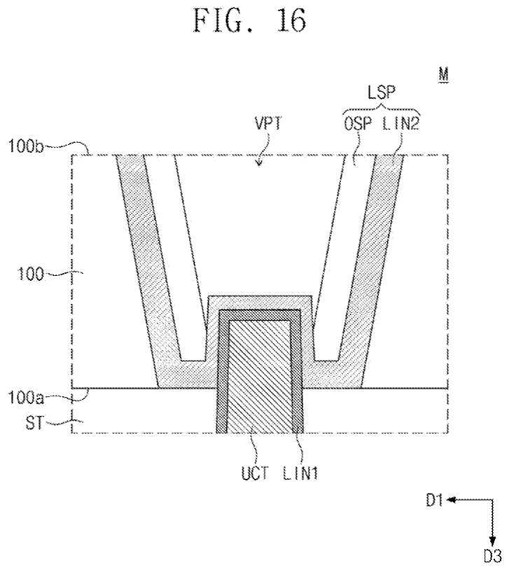

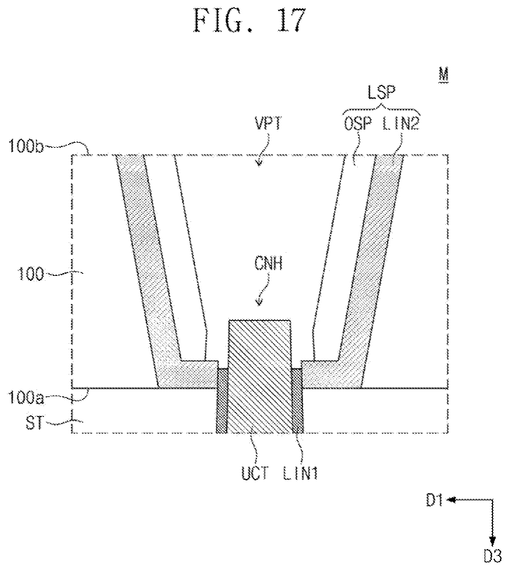

Referring to FIG. 17, the exposed first liner LIN1 may be selectively etched using the oxide spacer OSP as an etch mask. The etching process may be performed to completely expose an upper portion of the upper contact UCT. A portion of the oxide spacer OSP and a portion of the second liner LIN2 may also be removed together during the etching process.

A contact hole CNH exposing the upper portion of the upper contact UCT may be formed by the removal of the first liner LIN1. The contact hole CNH may expose three surfaces of the upper portion of the upper contact UCT.

Referring again to FIG. 6, the lower interconnection line trench VPT may be filled with a metal (e.g., copper or tungsten) to form the lower power interconnection line VPR1, VPR2 or VPR3. The metal filling the contact hole CNH may form a connection portion CNP of the lower power interconnection line VPR1, VPR2 or VPR3. The connection portion CNP may be in direct contact with the exposed portion of the upper contact UCT.

The descriptions to the same technical features as mentioned with reference to FIGS. 4 to 6 will be omitted and differences between the following embodiments and the embodiments of FIGS. 4 to 6 will be mainly described, for the purpose of ease and convenience in explanation.

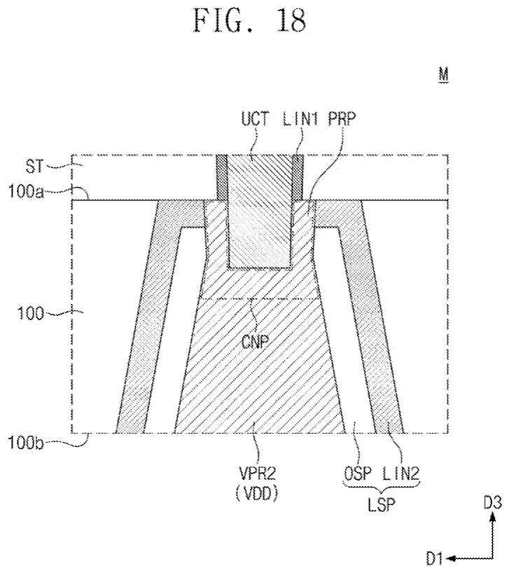

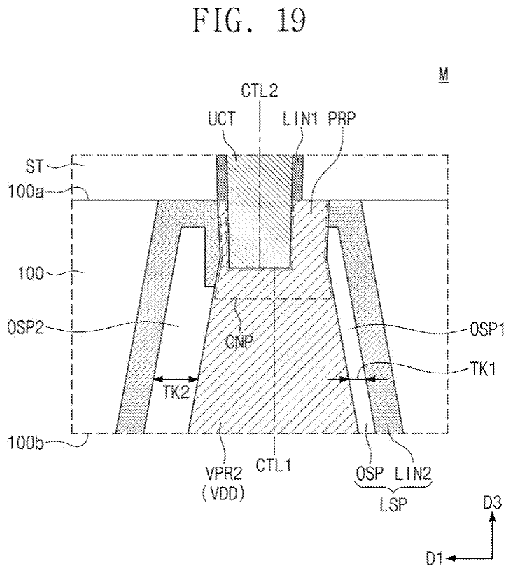

FIGS. 18 and 19 are enlarged cross-sectional views of the region ‘M’ of FIG. 5D of semiconductor devices according to example embodiments. Referring to FIG. 18, the first liner LIN1 and the second liner LIN2 may include the same material. A protrusion PRP of the connection portion CNP may be in contact with a bottom surface of the first liner LIN1 and a bottom surface of the device isolation layer ST. The first liner LIN1 and the second liner LIN2 may be spaced apart from each other by the protrusion PRP of the connection portion CNP.

Referring to FIG. 19, the second lower power interconnection line VPR2 may be misaligned with the upper contact UCT. More particularly, the second lower power interconnection line VPR2 may have a first center line CTL1, and the upper contact UCT may have a second center line CTL2. The first center line CTL1 and the second center line CTL2 may be offset from each other in the first direction D1.

An oxide spacer OSP may include a first oxide spacer OSP1 on a first side of the second lower power interconnection line VPR2, and a second oxide spacer OSP2 on a second side of the second lower power interconnection line VPR2. The first oxide spacer OSP1 and the second oxide spacer OSP2 may have different thicknesses. The first oxide spacer OSP1 may have a first thickness TK1, and the second oxide spacer OSP2 may have a second thickness TK2 greater than the first thickness TKL. This may be due to misalignment occurring in the photolithography process described above with reference to FIG. 16.

A width of the lower power interconnection line VPR1, VPR2 or VPR3 (in particular, a width of the connection portion CNP) according to the present embodiments may be relatively great. Thus, even though the misalignment described above occurs, the connection portion CNP may be in stable contact with the upper contact UCT. Thus, reliability of the semiconductor device may be improved.

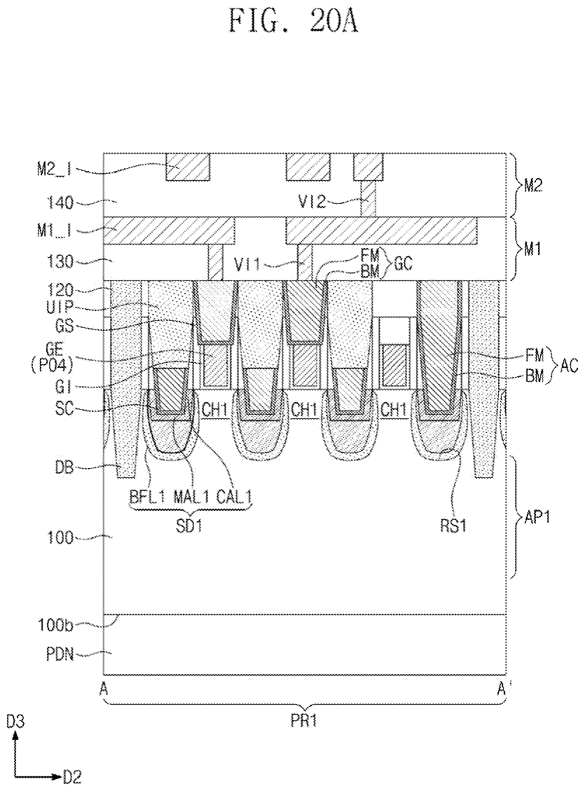

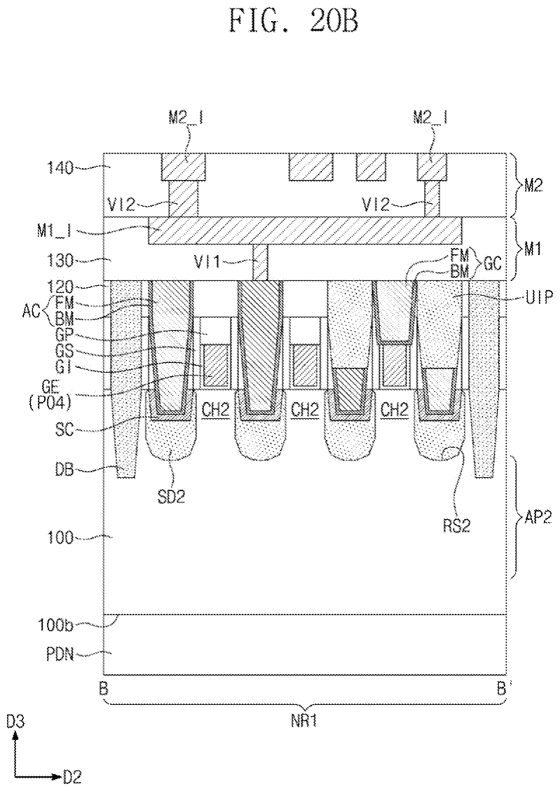

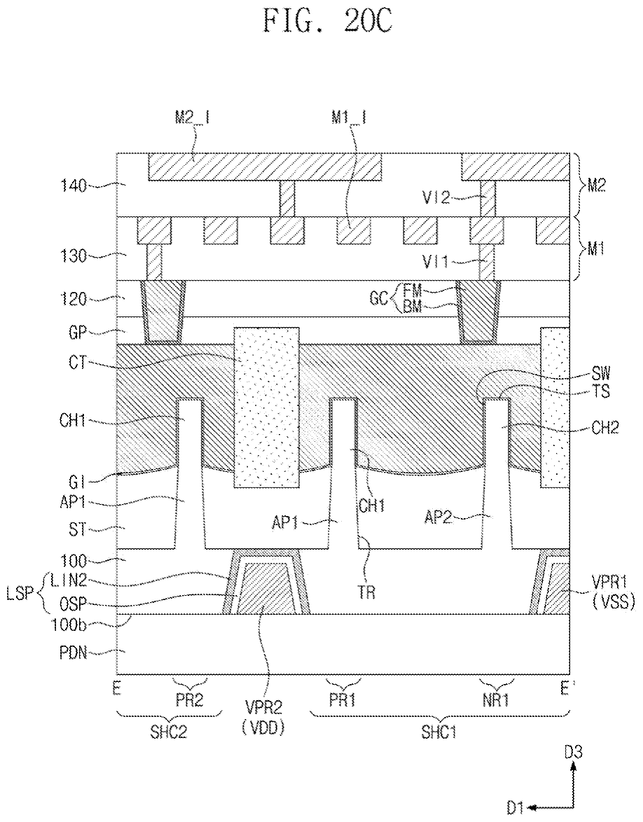

FIGS. 20A, 20B and 20C are cross-sectional views taken along the lines A-A′, B-B′ and E-E′ of FIG. 4, respectively, of a semiconductor device according to example embodiments. Referring to FIGS. 4 and 20A to 20C, a device isolation layer ST may define a first active pattern AP1 and a second active pattern AP2 on a substrate 100. The first active pattern AP1 may be defined on each of the first PMOSFET region PR1 and the second PMOSFET region PR2, and the second active pattern AP2 may be defined on each of the first NMOSFET region NR1 and the second NMOSFET region NR2.

The device isolation layer ST may cover a sidewall of a lower portion of each of the first and second active patterns AP1 and AP2. An upper portion of each of the first and second active patterns AP1 and AP2 may protrude above the device isolation layer ST (see FIG. 20C).

An upper portion of the first active pattern AP1 may include first source/drain patterns SD1 and a first channel pattern CH1 between the first source/drain patterns SD1. An upper portion of the second active pattern AP2 may include second source/drain patterns SD2 and a second channel pattern CH2 between the second source/drain patterns SD2.

Referring again to FIG. 20C, each of the first and second channel patterns CH1 and CH2 may not include the stacked first to third semiconductor patterns SP1, SP2 and SP3 described above with reference to FIGS. 5A to 5E. Each of the first and second channel patterns CH1 and CH2 may have a semiconductor pillar shape protruding above the device isolation layer ST.

A gate electrode GE may be on a top surface TS and both sidewalls SW of each of the first and second channel patterns CH1 and CH2. In other words, a transistor according to the present embodiments may be a three-dimensional field effect transistor (e.g., a FinFET) in which the gate electrode GE three-dimensionally surrounds a channel.

A first interlayer insulating layer 110 and a second interlayer insulating layer 120 may be on an entire top surface of the substrate 100. Active contacts AC may penetrate the first and second interlayer insulating layers 110 and 120 connected to the first and second source/drain patterns SD1 and SD2. A gate contact GC may penetrate the second interlayer insulating layer 120 and the gate capping pattern GP connected to the gate electrode GE. The active contacts AC and the gate contacts GC may be substantially the same as described above with reference to FIGS. 4 and 5A to 5E.

A third interlayer insulating layer 130 may be on the second interlayer insulating layer 120. A fourth interlayer insulating layer 140 may be on the third interlayer insulating layer 130. A first metal layer M1 may be provided in the third interlayer insulating layer 130. A second metal layer M2 may be provided in the fourth interlayer insulating layer 140. The first metal layer M1 and the second metal layer M2 may be substantially the same as described above with reference to FIGS. 4 and 5A to 5E.

First to third lower power interconnection lines VPR1, VPR2 and VPR3 may be provided in a lower portion of the substrate 100. A power delivery network layer PDN may be on the bottom surface 100b of the substrate 100. Each of the first to third lower power interconnection lines VPR1, VPR2 and VPR3 may be electrically connected to a corresponding one of the active contacts AC through a corresponding one of the upper contacts UCT. The first to third lower power interconnection lines VPR1, VPR2 and VPR3 and the power delivery network layer PDN may be substantially the same as described above with reference to FIGS. 4 and 5A to 5E.

The semiconductor device may effectively prevent a leakage current from the lower power interconnection line by the oxide spacer. Thus, the line width of the lower power interconnection line may be increased. The resistivity of the lower power interconnection line may be reduced, and a process defect caused by the misalignment between the lower power interconnection line and the upper contact may be prevented. The contact resistance between the lower power interconnection line and the upper contact may be reduced. As a result, the embodiments may improve the reliability and electrical characteristics of the semiconductor device.

By way of summation and review, a semiconductor device including a field effect transistor and a method of manufacturing the same is disclosed. As sizes and design rules of semiconductor devices have been reduced, MOSFETs have been scaled down. Operating characteristics of semiconductor devices may be deteriorated by reduction in size of MOSFETs. Accordingly, various methods for forming semiconductor devices which have excellent performance while overcoming limitations caused by high integration have been studied. A semiconductor device with improved electrical characteristics and reliability and a method of manufacturing a semiconductor device with improved electrical characteristics and reliability is disclosed.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device comprising:
a substrate including an active pattern;
a channel pattern and a source/drain pattern that are on the active pattern, the source/drain pattern connected to the channel pattern;
a gate electrode on the channel pattern;
an active contact on the source/drain pattern;
an upper contact being adjacent to the active contact and extending into the substrate;
a lower power interconnection line buried in the substrate; and
a power delivery network layer on a bottom surface of the substrate, wherein:
the lower power interconnection line includes a connection portion connected to the upper contact, and
a lower portion of the upper contact protrudes into the connection portion.

2. The semiconductor device as claimed in claim 1, wherein the connection portion is in direct contact with a bottom surface and both sidewalls of the upper contact.

3. The semiconductor device as claimed in claim 1, wherein:
a lower portion of the connection portion has a first width,
a central portion of the connection portion has a second width,
an upper portion of the connection portion has a third width,
the first width is greater than the second width, and
the third width is greater than the second width.

4. The semiconductor device as claimed in claim 1, wherein the connection portion has a sandglass shape.

5. The semiconductor device as claimed in claim 1, further comprising:
a metal layer on the active contact and the upper contact,
wherein the metal layer includes an interconnection line electrically connecting the active contact and the upper contact to each other.

6. The semiconductor device as claimed in claim 1, further comprising:
a first liner on a sidewall of the upper contact; and
a lower spacer between the lower power interconnection line and the substrate, wherein:
the lower spacer includes a second liner and an oxide spacer, and
the connection portion includes a protrusion extending toward the first liner.

7. The semiconductor device as claimed in claim 6, wherein:
the oxide spacer includes a first oxide spacer on a first side of the lower power interconnection line; and a second oxide spacer on a second side of the lower power interconnection line, and
a thickness of the first oxide spacer is different from a thickness of the second oxide spacer.

8. The semiconductor device as claimed in claim 1, wherein:
a width of the upper contact becomes progressively less toward the bottom surface of the substrate, and
a width of the lower power interconnection line becomes progressively greater toward the bottom surface of the substrate.

9. The semiconductor device as claimed in claim 1, wherein the power delivery network layer is configured to apply a source voltage or a drain voltage to the lower power interconnection line.

10. The semiconductor device as claimed in claim 1, wherein:
the channel pattern includes a plurality of semiconductor patterns stacked sequentially and spaced apart from each other, and
the gate electrode includes an inner electrode between adjacent ones of the plurality of semiconductor patterns; and an outer electrode outside the plurality of semiconductor patterns.

11. A semiconductor device comprising:
a substrate including an active pattern;
a channel pattern and a source/drain pattern that are on the active pattern, the source/drain pattern connected to the channel pattern;
a gate electrode on the channel pattern;
an active contact on the source/drain pattern;
an upper contact being adjacent to the active contact and extending into the substrate;
a first liner on a sidewall of the upper contact;
a lower power interconnection line buried in the substrate, the lower power interconnection line being in contact with the upper contact;
a lower spacer between the lower power interconnection line and the substrate; and
a power delivery network layer on a bottom surface of the substrate, wherein:
the lower spacer includes a second liner and an oxide spacer, and
the second liner includes a silicon-based insulating material different from that of the oxide spacer.

12. The semiconductor device as claimed in claim 11, wherein:
the first liner and the second liner include different materials, and
the first liner and the second liner are connected directly to each other.

13. The semiconductor device as claimed in claim 11, wherein:
the first liner and the second liner include the same material, and
the first liner and the second liner are separated from each other.

14. The semiconductor device as claimed in claim 11, wherein:
the oxide spacer includes a first oxide spacer on a first side of the lower power interconnection line; and a second oxide spacer on a second side of the lower power interconnection line, and
a thickness of the first oxide spacer is different from a thickness of the second oxide spacer.

15. The semiconductor device as claimed in claim 11, wherein:
the lower power interconnection line includes a connection portion connected to the upper contact, and
the connection portion includes a protrusion extending toward the first liner.

16. A semiconductor device comprising:
a substrate including an active pattern;
a channel pattern and a source/drain pattern that are on the active pattern, the source/drain pattern connected to the channel pattern;
a gate electrode on the channel pattern;
a gate insulating layer between the gate electrode and the channel pattern;
a gate spacer on a sidewall of the gate electrode;
a gate capping pattern on a top surface of the gate electrode;
an interlayer insulating layer covering the source/drain pattern and the gate capping pattern;
an active contact penetrating the interlayer insulating layer electrically connected to the source/drain pattern;
a metal-semiconductor compound layer between the active contact and the source/drain pattern;
a gate contact penetrating the interlayer insulating layer and the gate capping pattern electrically connected to the gate electrode;
an upper contact penetrating the interlayer insulating layer and extending into the substrate;
a first metal layer on the interlayer insulating layer, the first metal layer including a first interconnection line electrically connecting the active contact and the upper contact to each other;
a second metal layer on the first metal layer, the second metal layer including a second interconnection line electrically connected to the first metal layer;
a lower power interconnection line buried in the substrate;
a first oxide spacer and a second oxide spacer which are on both sides of the lower power interconnection line, respectively; and
a power delivery network layer on a bottom surface of the substrate,
wherein a thickness of the first oxide spacer is different from a thickness of the second oxide spacer.

17. The semiconductor device as claimed in claim 16, wherein:
the lower power interconnection line includes a connection portion connected to the upper contact, and
a lower portion of the upper contact protrudes into the connection portion.

18. The semiconductor device as claimed in claim 16, wherein:
a width of the upper contact becomes progressively less toward the bottom surface of the substrate, and
a width of the lower power interconnection line becomes progressively greater toward the bottom surface of the substrate.

19. The semiconductor device as claimed in claim 16, wherein:
the channel pattern includes a plurality of semiconductor patterns stacked sequentially and spaced apart from each other, and
the gate electrode includes an inner electrode between adjacent ones of the plurality of semiconductor patterns; and an outer electrode outside the plurality of semiconductor patterns.

20. The semiconductor device as claimed in claim 16, wherein the power delivery network layer is configured to apply a source voltage or a drain voltage to the lower power interconnection line.
